(19) United States
(12) Patent Application Publication
(10) Pub. No.: US 2024/0312778 A1
(43) Pub. Date: Sep. 19, 2024

(54) TEMPORARY CAPPING MATERIAL FOR OXIDE PREVENTION IN LOW TEMPERATURE DIRECT METAL-METAL BONDING

(71) Applicant: Lam Research Corporation, Fremont, CA (US)

(72) Inventors: Stephen J. BANIK, II, San Mateo, CA (US); Bryan L. BUCKALEW, Tualatin, OR (US); Stephen M. SIRARD, Austin, TX (US); Gregory BLACHUT, Campbell, CA (US); Ratchana LIMARY, Austin, TX (US); Diane HYMES, San Jose, CA (US); Justin OBERST, Beaverton, OR (US); Priyanka SURESH, Cleveland Heights, OH (US)

(21) Appl. No.: 18/044,336

(22) PCT Filed: Sep. 9, 2021
(86) PCT No.: PCT/US2021/049713

§ 371 Date: Mar. 7, 2023

Related U.S. Application Data
(60) Provisional application No. 63/076,861, filed on Sep. 10, 2020.

(51) Int. Cl. H01L 21/02; G03F 7/00

(52) U.S. Cl. CPC H01L 21/02334; G03F 7/70008; H01L 21/02277; H01L 21/0228

(57) ABSTRACT

The present disclosure relates to use of a stimulus responsive polymer (SRP) as a capping material during direct metal-metal binding. Processes and layers employing an SRP are described herein.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes. This application claims the benefit of U.S. Provisional Patent Application No. 63/076,861, filed Sep. 10, 2020, which is incorporated herein by reference in its entirety.

### FIELD

The present disclosure relates to use of a stimulus responsive polymer (SRP) as a capping material during direct metal-metal binding. Processes and layers employing an SRP are described herein.

### BACKGROUND

During semiconductor fabrication, direct metal-metal bonds can be formed using thermocompression, in which two clean metal features are brought into contact. Typically, a high quality bond requires a large force and a high temperature, which can damage critical components on next-generation chips and heterogeneous integration assemblies. Furthermore, some metals, such as copper, easily react with oxygen and form metal oxides at bonding interfaces, and such interfacial oxides can degrade bond quality and compromise chip performance.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

The present disclosure relates to a temporary capping material to protect surfaces prior to bonding. In particular embodiments, the capping material includes a stimulus responsive polymer (SRP), which can be deposited on sensitive surfaces to prevent oxide formation. Sensitive surfaces include substrates and metal features that are exposed during semiconductor processing, such as for integrated circuit (IC) and 3D IC fabrication. Prior to further processing, the capping material can be removed under mild conditions to provide a residue-free interface for optimal metal-metal bond formation. In some embodiments, SRP removal and metal-metal bonding are conducted under low temperature conditions and, optionally, within the same tool or apparatus.

Accordingly, in a first aspect, the present disclosure encompasses a method including: aligning a first capped feature with a second capped feature, wherein each of the first and second capped features includes, independently, a stimulus responsive polymer (SRP) layer disposed on a surface of a metal feature; and bonding the first and second capped features in an environment that removes the SRP and forms a metal-metal bond between the metal features. In some embodiments, the SRP layer prevents oxidation of the metal feature. In other embodiments, the SRP layer has a thickness of about 10 nm to 10 μm.

In some embodiments, wherein said bonding includes: exposing the first and second capped features to a removal temperature that removes the SRP, thereby providing exposed metal features; and contacting the exposed metal features to form the metal-metal bond. In some embodiments, the removal temperature is from about 50° C. to about 250° C.

In other embodiments, said exposing includes use of an acidic vapor, heat, an extreme ultraviolet light, an ultraviolet or vacuum ultraviolet light, a plasma, metastable neutrals from a noble gas plasma, or combinations thereof.

In some embodiments, said bonding includes a bonding temperature from about 25° C. to about 250° C. In other embodiments, said bonding includes use of an inert atmosphere, a vacuum environment, a reducing gas, or ambient air.

In further embodiments, the method includes (e.g., prior to said aligning): (i) depositing a first SRP layer on a surface of a first metal feature, thereby providing the first capped feature; and (ii) depositing a second SRP layer on a surface of a second metal feature, thereby providing the second capped feature. In some embodiments, the first SRP layer is further disposed on a surface of a gap fill layer surrounding the first metal feature. In other embodiments, the second SRP layer is further disposed on a surface of a gap fill layer surrounding the second metal feature. In other embodiments, the method includes (e.g., prior to said depositing in (i) and/or (ii)): pretreating a surface of the first and second metal features to clean the surface and/or to remove an oxide layer. In yet other embodiments, said depositing in (i) and/or (ii) includes vapor-based or solvent-based deposition of the SRP.

In a second aspect, the present disclosure encompasses a method including: depositing an SRP to form an SRP layer on a surface of a first metal feature including an electrical contact, thereby providing a first capped feature. In some embodiments, the method further includes (e.g., after said depositing): removing the SRP layer to provide a first exposed metal feature; and contacting the first exposed metal feature to a second exposed metal feature, thereby forming a metal-metal bond between the exposed metal features.

In some embodiments, wherein said depositing includes vapor-based or solvent-based deposition of the SRP. In other embodiments, said removing includes exposing the SRP layer to heat, an extreme ultraviolet light, an ultraviolet or vacuum ultraviolet light, metastable neutrals from a noble gas plasma, an acidic vapor, or a basic vapor.

In further embodiments, the method includes: depositing an SRP to form an SRP layer on a surface of the second metal feature, thereby providing a second capped feature; and removing the SRP layer from the second capped feature to provide the second exposed metal feature. In yet further embodiments, the method further includes: removing the SRP layer from the second capped feature to provide an exposed metal feature; and bonding the exposed first and second metal features, thereby forming a metal-metal bond.

In a third aspect, the present disclosure encompasses a method including: depositing an SRP to form an SRP layer on a surface of a first metal feature and a second metal feature, thereby providing a first capped feature and a second capped feature; aligning the first capped feature with the second capped feature: removing the SRP layer to provide exposed metal features; and contacting the exposed metal features, thereby forming a metal-metal bond between the exposed metal features.

In any embodiment herein, the SRP includes a ceiling temperature less than about 300° C. In some embodiments, the ceiling temperature is less than about 60° C., less than about 50° C., less than about 40° C., less than about 30° C., or lower.

In any embodiment herein, the SRP further includes an acid catalyst, an organic acid, a photoacid generator, or a thermal acid generator (e.g., any described herein).

In any embodiment herein, the SRP further includes a metal-binding moiety (e.g., any described herein). Non-limiting metal-binding moieties include optionally substituted heterocyclyl (e.g., an azole), optionally substituted heterocyclyloxy, optionally substituted heterocyclyloyl, thiol, optionally substituted amino, optionally substituted aminoalkyl, carboxyl, optionally substituted carboxyalkyl, hydroxyl, and/or optionally substituted hydroxyalkyl, and others described herein.

In any embodiment herein, the SRP includes a structure of one of formulas (I)-(XIII), (Ia), (Ib), or a salt thereof, as described herein.

In any embodiment herein, the SRP layer prevents oxidation of the first metal feature.

In any embodiment herein, the SRP layer has a thickness of about 10 nm to 10 μm.

In any embodiment herein, the metal features includes an electrical contact, a raised metal pillar, a bond pad, a bump, a microbump, a metal contact surrounded by a dielectric, or an interconnect.

In any embodiment herein, the metal feature (e.g., first metal feature and/or second metal feature) includes copper (Cu), tin (Sn), silver (Ag), gold (Au), aluminum (Al), or alloys thereof. Additional embodiments are described herein.

### Definitions

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈,

C₁₋₂₀, or C₁₋₂₄ alkoxy groups.

By “alkyl” and the prefix “alk” is meant a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) C₁₋₆ alkylsulfinyl (e.g., —S(O)-Ak, wherein Ak is optionally substituted C₁₋₆ alkyl); (3) C₁₋₆ alkylsulfonyl (e.g., —SO₂-Ak, wherein Ak is optionally substituted C₁₋₆ alkyl); (4) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (5) aryl; (6) arylalkoxy (e.g., —O-L-Ar, wherein L is a bivalent form of optionally substituted alkyl and Ar is optionally substituted aryl); (7) aryloyl (e.g., —C(O)—Ar, wherein Ar is optionally substituted aryl); (8) azido (e.g., —N₃); (9) cyano (e.g., —CN); (10) carboxyaldehyde (e.g., —C(O)H); (11) C₃₋₈ cycloalkyl (e.g., a monovalent saturated or unsaturated non-aromatic cyclic C₃₋₈ hydrocarbon group); (12) halo (e.g., F, Cl, Br, or I); (13) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (14) heterocyclyloxy (e.g., —O-Het, wherein Het is heterocyclyl, as described herein); (15) heterocyclyloyl (e.g., —C(O)-Het, wherein Het is heterocyclyl, as described herein); (16) hydroxyl (e.g., —OH); (17) N-protected amino; (18) nitro (e.g., —NO₂); (19) oxo (e.g., ═O); (20) C₃₋₈ spirocyclyl (e.g., an alkylene or heteroalkylene diradical, both ends of which are bonded to the same carbon atom of the parent group); (21) C₁₋₆ thioalkoxy (e.g., —S-Ak, wherein Ak is optionally substituted C₁₋₆ alkyl); (22) thiol (e.g., —SH); (23) —CO₂R^{A}, where R^{A} is selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (24) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (25) —SO₂R^{D}, where R^{D} is selected from the group consisting of (a) C₁₋₆ alkyl, (b) C₄₋₁₈ aryl, and (c) (C₄₋₁₈ aryl) C₁₋₆ alkyl (e.g., -L-Ar, wherein L is a bivalent form of optionally substituted alkyl group and Ar is optionally substituted aryl); (26) —SO₂NR^{E}R^{F}, where each of R^{E} and R^{F} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); and (27) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., L-Ar, wherein L is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -L-Cy, wherein L is a bivalent form of optionally substituted alkyl group and Cy is optionally substituted cycloalkyl, as described herein), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or

C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aralkyl” or “arylalkyl” is meant an aryl group, as defined herein, attached to the parent molecular group through an alkylene group, as defined herein. In some embodiments, the aralkyl group is -Ak-Ar, in which Ak is an optionally substituted alkylene, as defined herein, and Ar is an optionally substituted aryl, as defined herein. The aralkyl group can be substituted or unsubstituted. For example, the aralkyl group can be substituted with one or more substitution groups, as described herein for aryl and/or alkyl. Exemplary unsubstituted aralkyl groups are of from 7 to 16 carbons (C₇₋₁₆ aralkyl), as well as those having an aryl group with 4 to 18 carbons and an alkylene group with 1 to 6 carbons (i.e., (C₄₋₁₈ aryl)C₁₋₆ alkyl).

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl. In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “(aryl)(alkyl)ene” is meant a bivalent form including an arylene group, as described herein, attached to an alkylene or a heteroalkylene group, as described herein. In some embodiments, the (aryl)(alkyl)ene group is -L-Ar— or -L-Ar-L- or —Ar-L-, in which Ar is an arylene group and each L is, independently, an optionally substituted alkylene group or an optionally substituted heteroalkylene group.

By “azido” is meant an —N₃ group.

By “azidoalkyl” is meant an azido group attached to the parent molecular group through an alkyl group, as defined herein.

By “carboxyaldehyde” is meant a —C(O)H group.

By “carboxyalkyl” is meant an alkyl group, as defined herein, substituted by a carboxyl group, as defined herein.

By “carboxyl” is meant a —CO₂H group.

By “cyano” is meant a —CN group.

By “cycloalkenyl” is meant a non-aromatic carbon-based ring composed of three to ten carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “cycloalkylene” is meant a multivalent (e.g., bivalent) form of a cycloalkyl group, as described herein. Exemplary cycloalkylene groups include cyclopropylene, cyclobutylene, cyclopentylene, cyclohexylene, cyclohexenylene, cyclohexadienylene, etc. In some embodiments, the cycloalkylene group is a C₃₋₆, C₃₋₁₂, C₃₋₁₆, C₃₋₁₈, C₃₋₂₀, or C₃₋₂₄ cycloalkylene group. The cycloalkylene group can be branched or unbranched. The cycloalkylene group can also be substituted or unsubstituted. For example, the cycloalkylene group can be substituted with one or more substitution groups, as described herein for alkyl.

By “fluoroacid” is meant A¹CO₂H, where A¹ is an optionally substituted alkyl or an optionally substituted aryl substituted with one or more fluoro (F).

By “ester” as used herein is meant —OC(O)A¹ or —C(O)OA¹, where A¹ can be an alkyl, alkenyl, alkynyl, aryl, heteroaryl, cycloalkyl, cycloalkenyl, heterocycloalkyl, or heterocycloalkenyl group, as described herein.

By “ether” as used herein is meant A¹OA², where A¹ and A² can be, independently, an alkyl, alkenyl, alkynyl, aryl, heteroaryl, cycloalkyl, cycloalkenyl, heterocycloalkyl, or heterocycloalkenyl group, as described herein.

By “halo” is meant F, Cl, Br, or I.

By “haloalkyl” is meant an alkyl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant an alkylene group, as defined herein, containing one, two, three, four, or more non-carbon heteroatoms (e.g., independently selected from the group consisting of nitrogen, oxygen, phosphorous, sulfur, selenium, or halo). In some embodiments, the heteroalkylene group is -Ak-X—, —X-Ak-, -(Ak-X)ₕ₁-Ak-, or —X-(Ak-X)ₕ₁—, in which Ak is an optionally substituted alkylene, as defined herein, X is or includes a non-carbon heteroatom (e.g., —O—, —S—, or —NR^{N1}—, which R^{N1} is H, optionally alkyl, or optionally substituted aryl), and h1 is an integer from 1 to 5. The heteroalkylene group can be substituted or unsubstituted. For example, the heteroalkylene group can be substituted with one or more substitution groups, as described herein for alkyl. The heteroalkylene group can be linear or cyclic, such as a bivalent form of a heterocyclyl group formed by removing a hydrogen from a heterocyclyl group, as described herein. Exemplary cyclic heteroalkylene groups include piperdylidene, quinolinediyl, etc.

The term “heterocycloalkenyl” is a type of cycloalkenyl group, as defined herein, in which at least one of the carbon atoms of the ring is substituted with O, S, N, or NH. The cycloalkenyl group and heterocycloalkenyl group can be substituted or unsubstituted. The cycloalkenyl group and heterocycloalkenyl group can be substituted with one or more groups including, but not limited to, alkyl, alkoxy, alkenyl, alkynyl, aryl, heteroaryl, carboxyaldehyde, amino, carboxyl, sulfonic acid, sulfinic acid, fluoroacid, phosphonic acid, ester, ether, halo, hydroxyl, ketone, nitro, cyano, azido, silyl, sulfonyl, sulfinyl, or thiol, as described herein.

The term “heterocycloalkyl” is a type of cycloalkyl group, as defined herein, in which at least one of the carbon atoms and its attached hydrogen atoms, if any, are replaced by O, S, N, or NH. The heterocycloalkyl group and heterocycloalkenyl group can be substituted or unsubstituted. The cycloalkyl group and heterocycloalkyl group can be substituted with one or more groups including, but not limited to, alkyl, alkoxy, alkenyl, alkynyl, aryl, heteroaryl, carboxyaldehyde, amino, carboxyl, sulfonic acid, sulfinic acid, fluoroacid, phosphonic acid, ester, ether, halo, hydroxyl, ketone, nitro, cyano, azido, silyl, sulfonyl, sulfinyl, or thiol, as described herein.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “heterocyclyldiyl” is meant a bivalent form of a heterocyclyl group, as described herein. In one instance, the heterocyclyldiyl is formed by removing a hydrogen from a heterocyclyl group. Exemplary heterocyclyldiyl groups include piperdylidene, quinolinediyl, etc. The heterocyclyldiyl group can also be substituted or unsubstituted. For example, the heterocyclyldiyl group can be substituted with one or more substitution groups, as described herein for heterocyclyl.

By “heterocyclyloxy” is meant a heterocyclyl group, as defined herein, attached to the parent molecular group through an oxygen atom.

By “heterocyclyloyl” is meant a heterocyclyl group, as defined herein, attached to the parent molecular group through a carbonyl group.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “ketone” is meant A¹C(O)A², where A¹ and A² can be, independently, an alkyl, haloalkyl, alkenyl, alkynyl, aryl, heteroaryl, cycloalkyl, cycloalkenyl, heterocycloalkyl, or heterocycloalkenyl group, as described herein.

By “nitro” is meant an —NO₂ group.

By “oxy” is meant —O—.

By “phosphonic acid” is meant —P(O)(OH)₂.

By “silyl” is meant —SiA¹A²A³, where each of A¹, A², and A³ can be, independently, an alkyl, haloalkyl, alkenyl, alkynyl, aryl, heteroaryl, cycloalkyl, cycloalkenyl, heterocycloalkyl, or heterocycloalkenyl group, as described herein

By “sulfinic acid” is meant —S(O)OH.

By “sulfinyl” is meant —S(O)A₁, where A₁ can be hydrogen, an alkyl, haloalkyl, alkenyl, alkynyl, aryl, heteroaryl, cycloalkyl, cycloalkenyl, heterocycloalkyl, or heterocycloalkenyl group, as described herein.

By “sulfonic acid” is meant —S(O)₂OH.

By “sulfonyl” is meant —S(O)₂A¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group, as described herein.

By “thio” is meant an —S— group.

By “thiol” is meant an —SH group.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Other features and advantages of the invention will be apparent from the following description and the claims.

### BRIEF DESCRIPTION OF THE DRAWINGS

FIG. 1A-1B shows flow diagrams having certain operations in examples of semiconductor fabrication processes that use a stimulus response polymer (SRP). Provided are (A) a method 100 that employs SRP layers 118, 128 to form a bonded assembly 130; and (B) a bonding operation that includes removing SRP and contacting exposed features to form the bonded assembly 130.

FIG. 2A-2B shows flow diagrams having other certain operations. Provided are (A) a method employing thin layers 218, 228 of SRP and (B) another method employing thick layers 248, 258 of SRP.

FIG. 3 shows a flow diagram having yet other certain operations. Provided is a method employing a metal feature 314 surrounded by a gap fill material 315.

FIG. 4A-4D shows process flow diagrams for non-limiting methods that use SRP during a process that forms metal-metal bonds.

FIG. 5 shows a process flow diagram for another non-limiting method that uses SRP during a process that forms metal-metal bonds.

FIG. 6 shows a process flow diagram for yet another non-limiting method that uses SRP during a process that forms metal-metal bonds.

FIG. 7 is a functional block diagram of an example of an electroplating cell according to the present disclosure.

FIG. 8 is a functional block diagram of an example of an electrodeposition apparatus according to the present disclosure.

FIG. 9 is a functional block diagram of an example of another electrodeposition apparatus according to the present disclosure.

FIG. 10 is a functional block diagram of an example of an electroplating apparatus according to the present disclosure.

FIG. 11 is a functional block diagram of an example of a substrate processing system including multiple substrate processing tools and a storage buffer according to the present disclosure.

FIG. 12 depicts a cross-sectional schematic view of an example of a dry deposition apparatus for depositing an SRP according to the present disclosure.

FIG. 13 depicts detail side section and plan views of a portion of a top plate, substrate, and edge ring.

FIG. 14 is a plan view of an example of a wet deposition apparatus for depositing an SRP according to the present disclosure.

FIG. 15 is a sectional view along the line III-III in FIG. 14.

FIG. 16 is an enlarged view of the detail IV in FIG. 15.

FIG. 17 is a plan view of the heating assembly of an example of a wet deposition apparatus.

FIG. 18 shows another example of a wet deposition apparatus for depositing an SRP according to the present disclosure.

FIG. 19 shows the embodiment of FIG. 18 in a loading and unloading position.

### DETAILED DESCRIPTION

Stimuli responsive polymers (SRPs) may be used in semiconductor fabrication processes as temporary or sacrificial layers that can be later removed. Low ceiling temperature SRPs can be spontaneously removed when exposed to stimuli such as mildly elevated temperatures or acidic vapors, avoiding aggressive wet or dry removal chemistries that may harm the substrate surface. Other processes to remove SRPs are described herein. In particular embodiments, such SRPs can result in residue-free removal, thereby providing a clean surface amenable for forming a metal-metal bond.

Described herein are capping processes whereby an SRP is deposited on a metal feature (e.g., a plated metal feature) to serve as a protective layer. This temporary layer prevents oxide from forming on the feature as the wafer queues and is transferred to the thermocompression bonding tool. Once in the chamber of the thermocompression bonding tool, the temperature is ramped to a removal temperature (e.g., under 250° C.) to volatilize or bake off the capping material. Then, the metal features are aligned and brought into contact for a high quality bond. Thus, also described herein are bonding processes whereby the SRP is removed to form a metal-metal bond.

In use, the sacrificial films can provide queue-time extension. In one instance, the SRP film can be a thin or thick sacrificial polymer layer configured to protect sensitive metal features for extended periods, such as during substrate transfer and feature alignment or prior to thermocompressive bonding. The sacrificial surface protection layers can eventually be removed by triggering spontaneous depolymerization and vaporization of the protection layer above its ceiling temperature with the appropriate stimuli (e.g., acidic, thermal, and/or electromagnetic), thus minimizing the impact on the sensitive surfaces. Such surfaces can include those that are sensitive to environmental queue-time effects or susceptible to unwanted oxidation, corrosion, and/or halogenation. Examples of such surfaces include but are not limited to copper (Cu), tin (Sn), tin silver (SnAg), silver (Ag), gold (Au), aluminum (Al), silicon (Si), silicon/germanium (Si/Ge), tungsten (W), cobalt (Co), ruthenium (Ru), molybdenum (Mo), and titanium nitride (TiN).

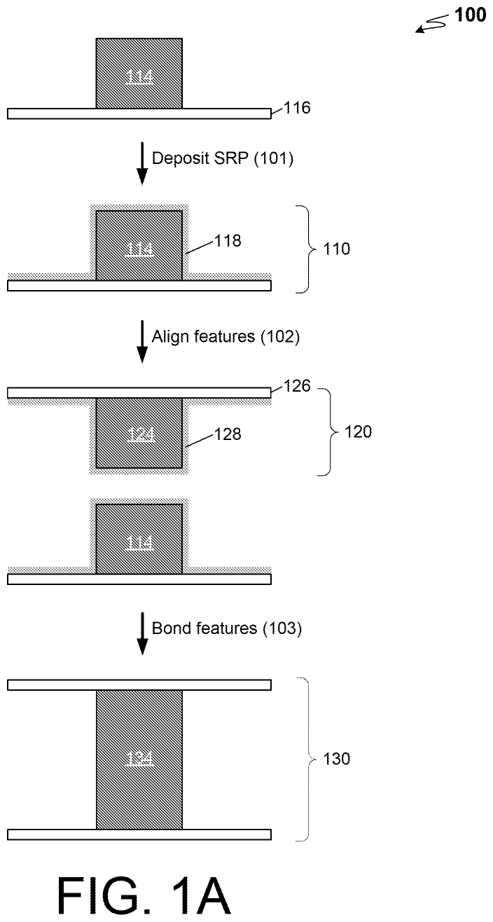

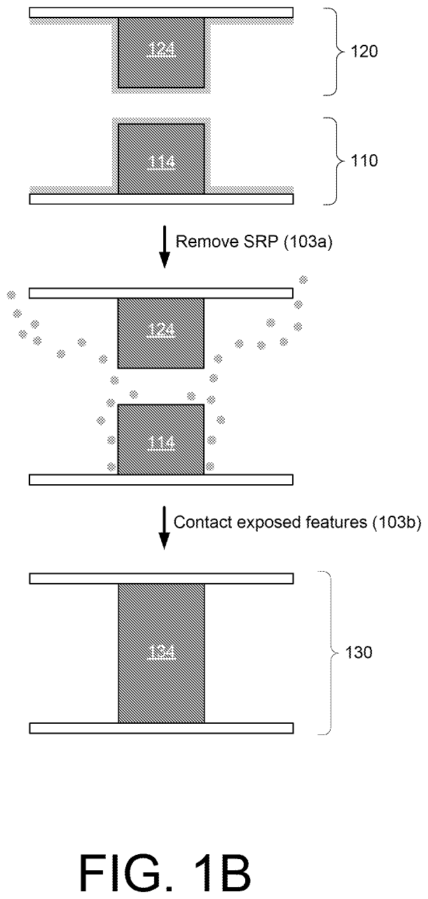

Turning to FIG. 1A, an example of a method 100 for protecting a metal feature is shown. First, a substrate 116 including a metal feature 114 is provided. The feature can be an electrical contact, such as a pillar (e.g., a raised metal pillar), a bond pad, a bump, a microbump, a metal contact surrounded by a dielectric, or an interconnect. In the next operation 101, an SRP is deposited on a surface of the metal feature 114 to form an SRP layer 118. The SRP can be deposited in a vapor phase (e.g., with a carrier gas) or in a liquid phase (e.g., with a solvent or as a formulation). When using solvent-base deposition, the SRP can be optionally dried or solidified by removing the liquid portion, thereby forming the layer or film.

The SRP can be a low ceiling temperature (T_{c}) polymer (e.g., homopolymer or copolymer) that is thermodynamically unstable at room temperature. T_{c} is the temperature at which both the polymer and its monomers are present at equilibrium. Below T_{c}, it is a polymer and above T_{c} it is monomer. Such low T_{c} polymers can be kinetically trapped as polymers with excellent shelf-life at temperatures well above T_{c}. For example, poly(phthalaldehyde) (PPHA) has a T_{c} of −40° C. but is stable at room temperature for 2.5 years. Stability is achieved by kinetically inhibiting the mechanism of depolymerization. Additional SRPs, as well as formulations thereof, are described herein.

The SRP can be deposited in any useful manner. The low T_{c} volatilizing polymer capping layer may be formulated with only a spin coat solvent, it may be dry deposited from vapor phase, or it may be formulated with a spin coat solvent and weak acids to lower degradation temperature. An apparatus such as a tape coater (doctor blade) could be used to coat thick (e.g., more than 1 μm) films, with some modifications to the formulation.

For wet deposition, the choice of solvent that is used for the spin coating formulation can impact the amount of residual solvent that remains in the polymer layer or film. Residual solvent can plasticize the polymer, lowering its glass transition temperature. By plasticizing the polymers, filling of features and relaxing of stresses from the spin coating process at temperatures below the degradation temperature of the polymer can be achieved. Such features can include high density features (e.g., having a pitch of less than about 20 μm between features), high aspect ratio features (e.g., having high aspect ratios (ARs), such as at least 8, 10, 20, 30, 40, or 80), and/or thick features (e.g., having a thickness of about 30 μm to 50 μm).

Furthermore, the SRP can be formulated with an acid catalyst, such as a weak organic acid (e.g., pKa ≥1). These weak organic acids can catalyze the degradation of the SRP without compromising the film's stability. By catalyzing the polymer degradation, the onset degradation temperature can be lowered, and the degradation rate can be increased.

The SRP can be deposited as a uniform or non-uniform layer on a feature. In addition, the thickness of the SRP layer can be about 10 nm to 10 μm. Depending on the dimensions of the feature, the SRP layer can provide conformal or non-conformal step coverage or planar coverage. If vias or openings are present, then the SRP layer can be used to fill such openings.

Turning again to FIG. 1A, after SRP deposition, a capped feature 110 is formed. The capped feature can include an SRP layer 118 disposed on any exposed surface of the metal feature 114. In some instances, the metal feature can be surrounded by another material (e.g., a dielectric material or a gap fill material), and the SRP layer is disposed on the exposed top surface of the feature. In other instances, the metal feature can be a pillar having exposed top and side surfaces, and the SRP layer is disposed on those surfaces or a portion thereof. The capped feature can be employed immediately, as well as stored or queued before further processing.

Further processing can include aligning 102 a first capped feature 110 with a second capped feature 120, which in turn can include an SRP layer 128 disposed on a surface of the second metal feature 124 on a substrate 126. The second capped feature can be formed by using any of the SRP deposition processes herein. Alignment can include vertically and/or horizontally aligning the top surfaces of the first and second metal features. In FIG. 1A, the top surface of the first feature 114 is distal to the substrate 116, and the top surface of the second feature 124 is distal to the substrate 126.

In operation 103, the features 114, 124 can undergo metal-metal bonding to form a metal structure 134 within a bonded assembly 130. In some non-limiting embodiments, the bonded assembly does not include solder. In other embodiments, the bonded assembly includes a direct metal-metal bond. In yet other embodiments, the metal structure provides a reduction in interconnect wire length, which can enhance performance and reduce power consumption. Such bonded assemblies can be present in any useful stack, device, substrate, vertically integrated architecture, multilayer integrated architecture, or high pitch density circuit. For instance, direct metal-metal bonding can enable tighter pitch (e.g., denser packing in the x-y direction, in which the axes are parallel to the plane of the substrate) and/or shorter connection height or length (e.g., in the z direction, in which the axis is orthogonal to the plane of the substrate).

Bonding can include removing the SRP layers 118, 128, thereby providing exposed features; and contacting the exposed features to form a metal-metal bond. Conditions for removing the SRP can include exposure to a removal temperature at which degraded SRP is volatile, and conditions for bonding can include exposure to a bonding temperature at which metal-metal bonds are formed. When the removal temperature and the bonding temperature are similar, then one continuous operation can be conducted at a temperature condition to remove the SRP and from a metal-metal bond. Alternatively, removing and contacting can be performed as discrete operations. Non-limiting removal temperatures include from about 50° C. to about 250° C., such as about 50° C. to 150° C.; and non-limiting bonding temperatures include from about 25° C. to about 250° C., such as about 100° C. to 250° C.

As further seen in FIG. 1B, operation 103a includes removing the SRP from the first capped feature 110 and the second capped feature 120, thereby providing a first exposed metal feature 114 and a second exposed metal feature 124. The capped feature can be exposed to a stimulus to degrade all of or only a portion of the SRP. Volatile monomers or fragments from the degraded polymer can be removed (e.g., by purging the chamber). The stimulus can be any that scissions bonds of the SRP to degrade it.

Controlled SRP degradation can include depolymerization, which can be catalyzed by the presence of an acid. Such catalysis can be promoted by formulating the SRP with an acid (e.g., a weak organic acid, a photoacid generator, or a thermal acid generator). In other embodiments, SRP removal can be conducted in the presence of an acidic vapor (e.g., formic acid, acetic acid, citric acid, or others herein) to catalyze the breakdown reaction. Acid use can promote degradation at lower temperatures (e.g., less than 100° C.), as well as incidentally remove metal oxide formed on the metal feature. Other methods of removal include use of heat, an extreme ultraviolet light (EUV), an ultraviolet light (UV), or a vacuum UV, which can be combined with an acidic vapor, as described herein. In other embodiments, SRP removal can include use of heat with another stimulus, such as with UV exposure or acid vapor exposure.

Turning again to FIG. 1B, operation 103b includes contacting the exposed features to provide a bonded metal structure 134 within the assembly 130. In particular embodiments, the bonding process enables high-integrity metal-metal direct bonding at low temperatures (e.g., under 250° C.) and makes use of low T_{c} volatilizing SRPs to prevent oxide formation. In some embodiments, the temporary capping layer volatilizes cleanly from the surface at low temperatures (e.g., between about 50° C. and 250° C.) to address oxide formation while enabling metal-metal bonding at low temperatures (e.g., below 250° C.). Such contacting can include thermocompression bonding, in which heat and pressure are applied to the metal features to allow for atomic interdiffusion and grain growth at the metal-metal interface.

SRP removal and thermocompression can occur in any traditional thermocompression tool or chamber with an inert atmosphere (e.g., no oxygen), vacuum, a reducing gas, or ambient air (e.g., including oxygen). Depending on conditions, the queue time can be controlled and minimized to prevent oxide formation. For example, if ambient air contains oxygen, then bonding can immediately follow volatilization of capping layer. Otherwise, an oxide may eventually form on feature surfaces.

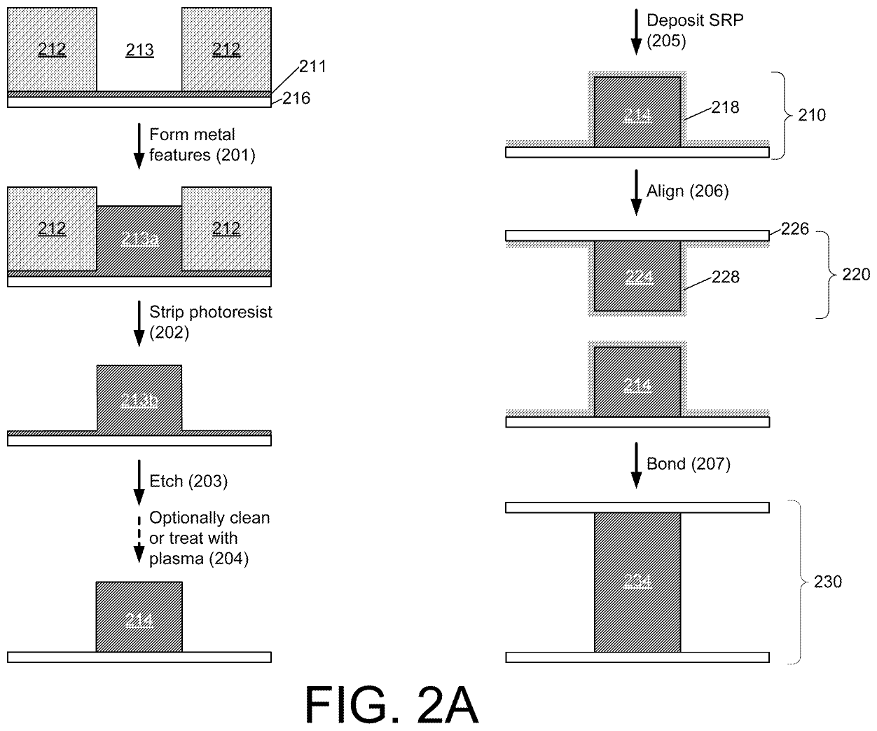

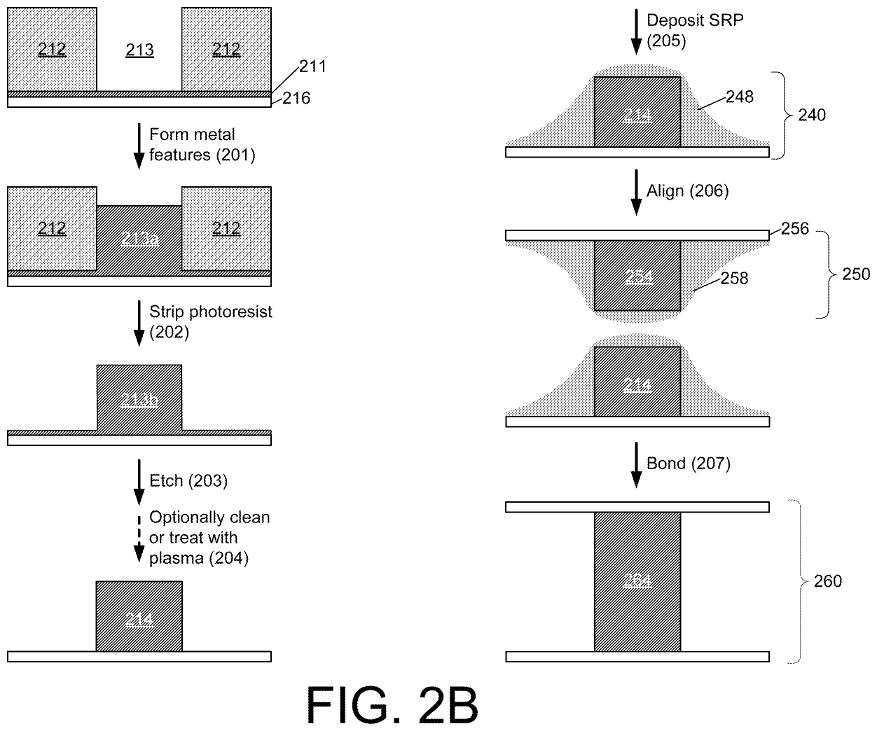

The processes herein include any useful combination of operations to form features, deposit SRP layers, and bond exposed features. As seen in FIG. 2A, a non-limiting process can include applying a temporary capping layer to a device having a plated metal feature. Initially, the stack can include a substrate 216, a seed layer or barrier layer 211 disposed on a surface of the substrate, and a patterned photoresist 212 having an opening 213 defined therein and disposed on a surface of the seed/barrier layer. In operation 201, a plated metal pillar 213a is formed within the opening 213. Next, in operation 202, the photoresist is stripped to provide a released metal pillar 213b. Operation 203 includes etching away the seed/barrier layer to provide a freestanding or isolated metal feature 214. Optionally, operation 204 can be conducted to clean the surface of the metal feature with a wet clean process or a plasma treatment process. Such a cleaning step can be performed immediately before depositing the SRP layer, thus ensuring a clean, oxide-free surface prior to capping.

In operation 205, an SRP layer 218 is deposited on exposed surfaces, which can include a top surface and/or sidewalls of the metal feature 214 and, optionally, a surface of the substrate 216. The first capped feature 210 is thus formed. In a similar manner, a second capped feature 220 can be formed. While the first and second capped features are shown to have similar geometry in FIG. 2A, each feature can be the same or different. In one non-limiting instance, the first capped feature can be a pillar, and the second capped feature can be a contact pad. In other embodiments, both the first and second capped features can be a pillar having similar or different dimensions.

In operation 206, the first capped feature 210 is aligned with the second capped feature 220, which includes a substrate 226, a second metal feature 224, and an SRP layer 228. Then, in operation 207, the first and second features are bonded together to form a metal structure 234 within the bonded assembly 230. As described herein, such bonding can include continuous or discrete operations to remove the SRP layers 218, 228 and contact the exposed features 214, 224 to form the metal-metal bond. Furthermore, the capping material need not be fully removed or volatilized, as long as a sufficient amount is removed from the bonding surfaces of the features to permit low temperature bonding. In some instances, the capping material can be retained within the stack or assembly after bonding the features.

The capping material need not be uniformly applied to the surface of the feature and/or substrate. As seen in FIG. 2B, the first capped feature 240 can include a non-uniform SRP layer 248 having variable thicknesses in proximity to the metal feature 214. Such non-uniformity can result from the dimension, aspect ratio, pitch density, surface chemistry, or material composition at the deposition surface. Capped features having uniform or non-uniform SRP layers are encompassed by the present disclosure.

Turning again to FIG. 2B, in operation 206, the first capped feature 240 can be aligned with a second capped feature 250 having a non-uniform SRP layer 258, a metal feature 254, and a substrate 256. As can be seen in operation 207, bonding provides a metal structure 264 within the bonded assembly 260.

Metal-metal bonds can be formed between features provided in any useful device. In some instances, the device includes freestanding or isolated metal features, such as pillars. Yet, in other instances, such features can be embedded within layers, and only the bonding surface is accessible on a surface of the device.

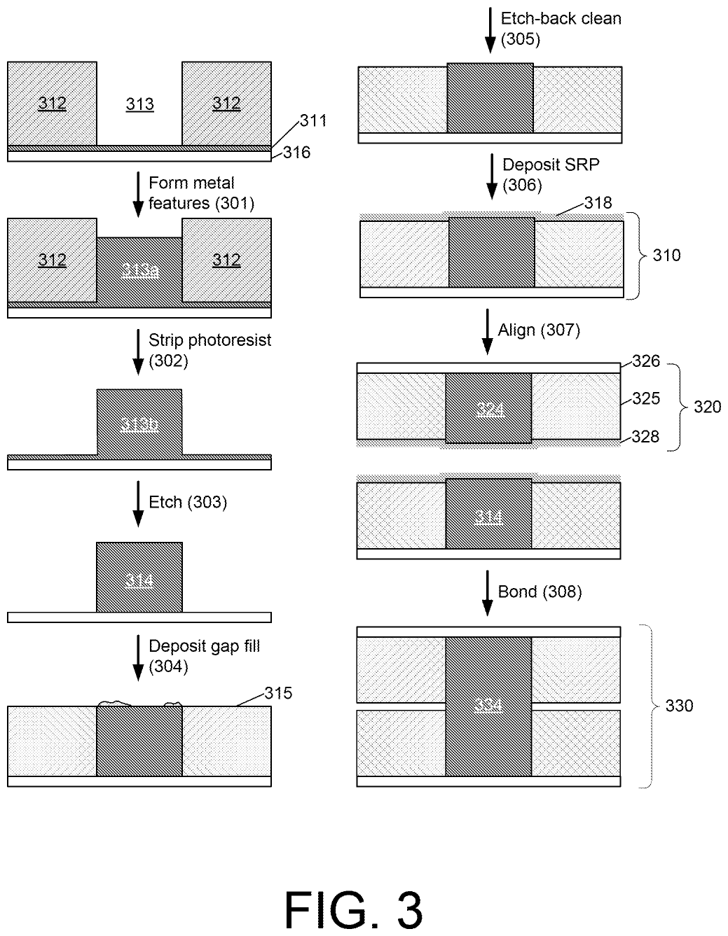

As seen in FIG. 3, a non-limiting process can include applying a temporary capping layer to a device having a gap fill material that surrounds a plated metal feature. Initially, the stack can include a substrate 316, a seed layer or barrier layer 311, and a patterned photoresist 312 having an opening 313 defined therein. In operation 301, a plated metal pillar 313a is formed within the opening 313. Next, in operation 302, the photoresist is stripped to provide the released metal pillar 313b. Operation 303 includes etching away the seed/barrier layer to provide the freestanding or isolated metal feature 314.

Operation 304 includes depositing a gap fill material around the metal feature 314, which can lead to incidental deposition on the metal surface. Thus, operation 305 includes etch-back cleaning the stack, which leads to etching away a portion of the gap fill layer and cleaning the metal surface prior to capping. Such etch-back cleaning can include use of reducing chemistry, e.g., ammonia or a combination of nitrogen (N₂) and hydrogen (H₂) gases. Next, in operation 306, an SRP layer 318 is deposited on exposed surfaces, which can include a surface of the metal feature 314 and a surface of the gap fill layer 315. The first capped feature 310 is thus formed. In a similar manner, a second capped feature 320 can be formed having a second SRP layer 328, a second metal feature 324, a gap fill layer 325, and a second substrate 326.

In operation 307, the first capped feature 310 is aligned with the second capped feature 320. Aligning can include arranging the top surfaces of each capped feature, such that vertical compression will provide contact between the surfaces and create a metal-metal bond. Then, in operation 308, the first and second features are bonded together to form a metal structure 334 within the bonded assembly 330. As described herein, such bonding can include continuous or discrete operations to remove the SRP layers 318, 328 and to contact the exposed features 314, 324, thereby forming the metal-metal bond. In some instances, removal of the SRP includes only exposing the surface of the metal feature, such that only a portion of the SRP layer is removed.

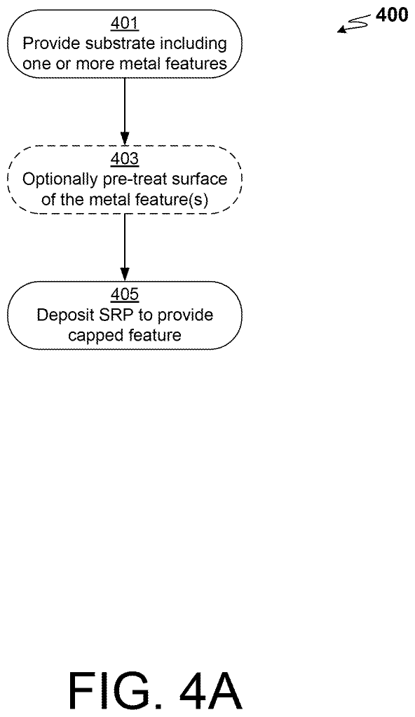

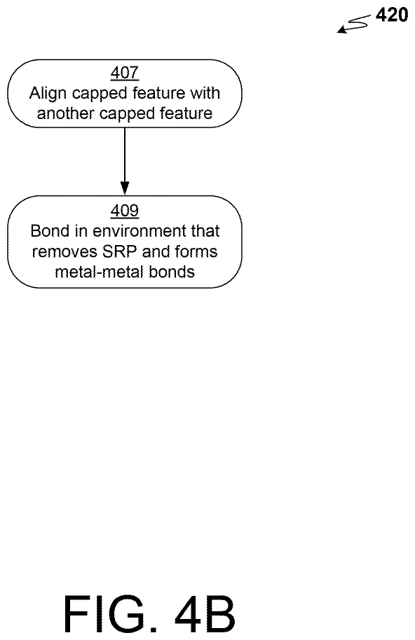

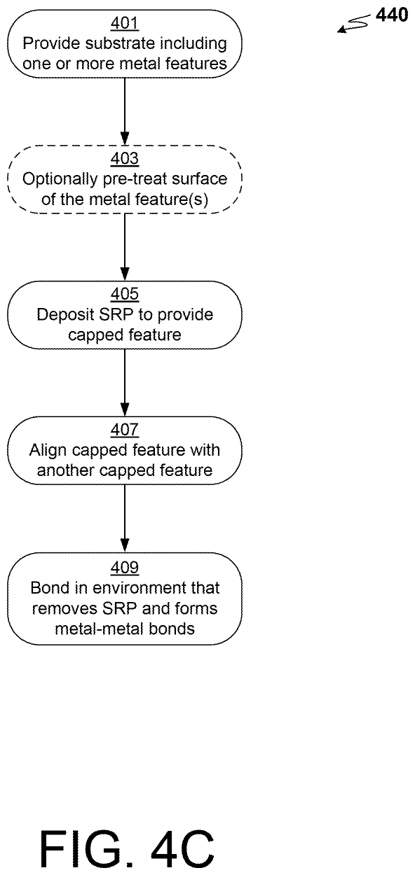

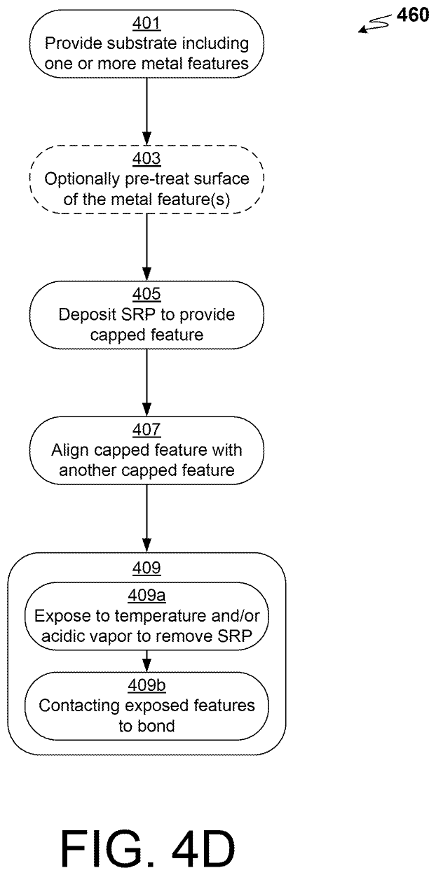

The present disclosure generally encompasses use of an SRP with a metal feature, such as an electrical contact. One non-limiting method can include forming an SRP layer on a first metal feature, thereby providing a first capped feature. As seen in FIG. 4A, an example of a method 400 includes operation 401 of providing a substrate including one or more metal features (e.g., electrical contact(s)) and operation 405 of depositing an SRP on a surface of metal feature(s) to form an SRP layer, thereby providing a capped feature. Such a method can optionally include operation 403 of pre-treating a surface of the metal feature prior to SRP deposition, in which such pre-treatment can include a wet clean process or a plasma process (e.g., a non-thermal plasma process). Methods herein can include one or more pre-bonding operations (e.g., prior to SRP deposition), such as cleaning metal features, isolating metal features by depositing dielectric or gap fill materials, and recessing one or more non-metallization layers.

Another non-limiting method can include aligning capped features having an SRP layer. As seen in FIG. 4B, an example of a method 420 includes operation 407 of aligning the first and second capped features, in which each capped feature includes an SRP layer disposed on a surface of a metal feature; and operation 409 of bonding the first and second capped features in an environment that removes the SRP and forms a metal-metal bond between the metal features. Such an environment can possess any removal temperature or bonding temperature described herein. Furthermore, the exposed features can be contacted with a contact pressure that facilitates metal-metal bond formation, such as a pressure of about 0.2 MPa to about 1 MPa or about 0.7 MPa (about 100 psi). Methods herein can include one or more post-bonding operations, such as annealing of the metal structure within the bonded assembly, wafer thinning, or other backside processing.

Other methods can include SRP deposition, alignment of capped features, and bonding. As seen in FIG. 4C, an example of a method 440 includes operation 401 of providing a substrate including one or more metal features; optional operation 403 of pre-treating a surface of the metal feature(s) to provide a clean surface and/or an oxide-free surface; operation 405 of depositing an SRP on a surface of metal feature(s), thereby providing a first capped feature; operation 407 of aligning the first capped feature with a second capped feature having an SRP layer disposed on a surface of a metal feature; and operation 409 of bonding the first and second capped features in an environment that removes the SRP and forms a metal-metal bond between the metal features.

Bonding can include discrete steps, if desired. As seen in FIG. 4D, the method 460 can include a bonding operation 409 that includes operation 409a of removing the SRP, such as by exposing to a removal temperature to volatize the SRP and/or exposing to an acidic vapor to catalyze SRP removal; and operation 409b of contacting the exposed features to provide a metal-metal bond. Such contacting can be conducted at any bonding temperature and/or contact pressure described herein.

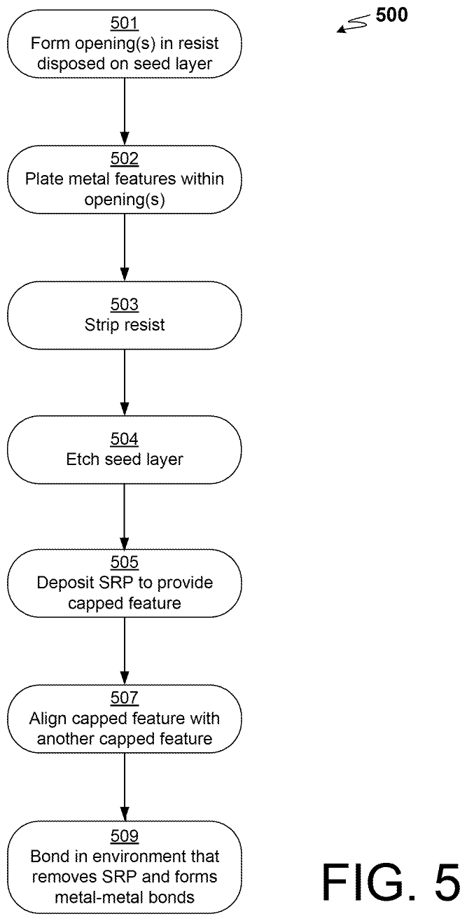

Processes herein can include further operations to form the stack prior to SRP deposition. As seen in FIG. 5, the example of method 500 can include operation 501 of forming one or more openings in a resist layer, which may be optionally disposed on a seed layer or a barrier layer; operation 503 of plating or depositing metal within the opening(s) to provide one or more metal features; operation 503 of stripping the resist layer, thereby releasing the metal feature(s); operation 504 of etching the seed/barrier layer to provide freestanding or electrically isolated metal feature(s); operation 505 of depositing an SRP on a surface of metal feature(s), thereby providing a first capped feature; operation 507 of aligning the first capped feature with a second capped feature having an SRP layer disposed on a surface of a metal feature; and operation 509 of bonding the first and second capped features in an environment that removes the SRP and forms a metal-metal bond between the metal features.

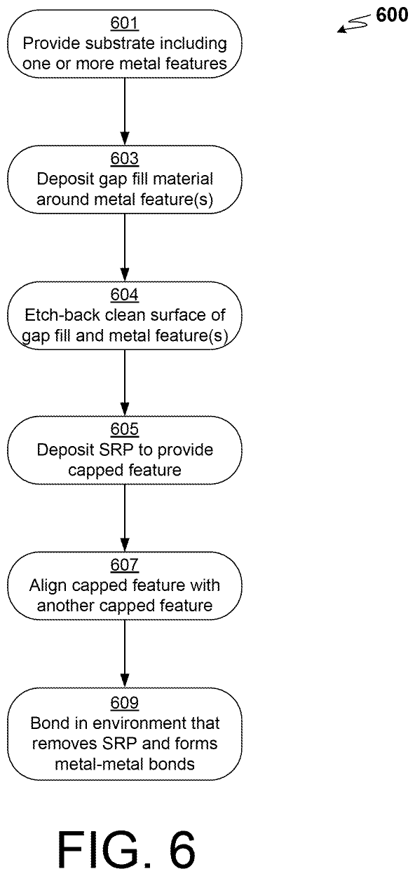

The stack can include further materials in use with metal features, and methods herein can include operations to deposit such materials. As seen in FIG. 6, the example of method 600 can include operation 601 of providing a substrate including one or more metal features; operation 603 of depositing a gap fill material around the metal feature(s), thereby electrically isolating these features; operation 604 of etch-back cleaning a surface of the gap fill material and a surface of the metal feature(s); operation 605 of depositing an SRP on the cleaned surface of metal feature(s), thereby providing a first capped feature; operation 607 of aligning the first capped feature with a second capped feature having an SRP layer disposed on a surface of a metal feature; and operation 609 of bonding the first and second capped features in an environment that removes the SRP and forms a metal-metal bond between the metal features.

### Metal Features and Substrates

The SRPs, and methods herein, can be used with metal features and related structures. Such metal features can exhibit oxide formation during exposure to air, and such interfacial oxide layers should be avoided when forming metal-metal bonds. Thus, in one aspect, the SRPs herein can be employed to reduce oxidation of such metal features.

The SRP can be disposed on any useful feature, substrate, or surface. The surface may be a planar surface or include one or more electrical contacts, pillars, bond pads, bumps, microbumps, interconnects, vias, holes, gaps, and trenches. Yet other surfaces can include those on devices, such as electronic components, printed circuit boards, packages, and others. Examples of substrate surfaces include silicon, silicon germanium, and germanium structures; metal surfaces including but not limited to copper, cobalt, titanium, titanium nitride, tungsten, ruthenium, or molybdenum; and/or other structures and materials. In particular, a metal feature can include a conductive metal, a transition metal, as well as alloys or doped forms thereof.

### Deposition of SRPs

In many embodiments, the SRPs are low ceiling temperature (T_{c}) polymers. T_{c} is the equilibrium temperature between a polymer and its monomers. As used herein, the term “low T_{c}” refers to T_{c} values below a removal temperature. In some embodiments, the T_{c} is below room temperature, such that the polymers are thermodynamically unstable at room temperature. Instead, the low T_{c} polymer is kinetically trapped to allow prolonged storage at room temperature. In some examples, the stable storage period is on the order of months or years. Low T_{c} polymers will rapidly de-polymerize to its monomer constituents if an end-group or main chain bond is broken. Thus, the polymer de-polymerizes in response to stimuli such as an acidic catalyst, a basic catalyst, extreme ultraviolet (EUV) light, ultraviolet (UV) light, heat, thermal catalyst, and/or photocatalyst. The monomer products are volatile and leave or can be easily removed from the surface and chamber.

While in some embodiments, the T_{c} is below room temperature, in the context of semiconductor processing, low T_{c} may also refer to ceiling temperatures that are higher than room temperature. For example, removal temperatures of up to 300° C. may be used, meaning that the ceiling temperature is below 300° C.

In some embodiments, the SRP can include one or more metal-binding moieties. The metal-binding moiety can facilitate binding or adhesion of the SRP layer to the metal feature. In addition, such moieties can be present within a particular number or percentage of monomers within a polymer. In other embodiments, the SRP can be a copolymer, in which one of the monomers includes at least one metal-binding moiety.

Non-limiting metal-binding moieties can include one or more of the following: optionally substituted heterocyclyl, optionally substituted heterocyclyloxy, optionally substituted heterocyclyloyl, thiol (—SH), optionally substituted amino (e.g., —NH₂ or —NR^{N1}R^{N2}), optionally substituted aminoalkyl (e.g., -Ak-NH₂ or -Ak-NR^{N1}R^{N2}), carboxyl (—CO₂H), optionally substituted carboxyalkyl (e.g., -Ak-CO₂H), hydroxyl (—OH), and/or optionally substituted hydroxyalkyl (e.g., -Ak-OH), in which Ak is an optionally substituted alkylene, and in which each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein. In particular embodiments, the optionally substituted heterocyclyl includes an optionally substituted azole group, such as optionally substituted imidazolyl, isoxazolyl, isothiazolyl, oxadiazolyl (e.g., 1,2,3-oxadiazolyl, 1,2,4-oxadiazolyl, 1,2,5-oxadiazolyl, or 1,3,4-oxadiazolyl), oxazolyl, pyrazolyl, tetrazolyl, thiadiazolyl (e.g., 1,2,3-thiadiazolyl, 1,2,4-thiadiazolyl, 1,2,5-thiadiazolyl, or 1,3,4-thiadiazolyl), thiazolyl, triazolyl (e.g., 1,2,3-triazolyl or 1,2,4-triazolyl), or any described herein.

In other embodiments, the metal-binding moiety is a polydentate (e.g., bidentate, tetradentate, or octadentate) ligand. Non-limiting polydentate ligands include R¹-L¹-R², in which L¹ is optionally substituted alkylene, optionally substituted heteroalkylene, optionally substituted arylene, or optionally substituted heterocyclyldiyl; and each of R¹ and R² comprises, independently, thiol, optionally substituted amino, carboxyl, or hydroxyl. In some embodiments, each of R¹ and R² is, independently, -L²-R³; L² is a covalent bond, optionally substituted alkylene, or optionally substituted heteroalkylene; and each R³ is, independently, thiol, optionally substituted amino, carboxyl, or hydroxyl.

Another non-limiting polydentate ligand includes R¹-L¹-R², in which L¹ is optionally substituted alkylene; and each of R¹ and R² comprises, independently, optionally substituted heterocyclyl (e.g., an optionally substituted azole). In yet other embodiments, the metal-binding moiety is a Schiff base ligand. Yet other metal-binding moieties include imidazolyl, pyrazolyl, triazolyl, thiol, nitrile, 3,4-dihydroxyphenylalanine (DOPA), histidine, ethylenediamine, 1,4,7,10-tetraazacyclododecane-1,4,7,10-tetraacetic acid (DOTA), as well as derivatives thereof.

Example of SRPs are provided below. However, the methods described herein may be used with any SRPs. In some embodiments, the SRPs are homopolymers or copolymers including poly(aldehydes). In particular embodiments, they may be self-immolative polymers as described in U.S. Patent Publication No. 2018/0155483, which was published on Jun. 7, 2018 and which is hereby incorporated herein by reference in its entirety.

SRPs can be any appropriate polymer (e.g., homopolymer or copolymer) in linear or cyclic form. Non-limiting SRPs include a poly(phthalaldehyde), a poly(aldehyde), a poly(benzyl carbamate), a poly(benzyl ether), a poly(alpha-methyl styrene), a poly(carbonate), a poly(norbornene), a poly(olefin sulfone), a poly(glyoxylate), a poly(glyoxylamide), a poly(ester), or a poly(methyl methacrylate), as well as derivatives thereof. Such derivatives can include replacement of oxy (—O—) with an optionally substituted heteroalkylene, as defined herein, as well as substitutions with one or more substitution groups, as described herein for alkyl.

Yet other SRPs can include those having a structure of one of formulas (I)-(XV), (Ia), (Ib), or (Ic). Such SRPs can be a linear polymer or a cyclic polymer. If linear, the polymer can include any useful end groups that terminate the molecule. Such end groups can depend on the reactive end groups present on the monomers employed to synthesize the polymer. In particular embodiments, end groups can include those fragments formed from use of an anionic initiator (e.g., fragments such as alkyl anion, e.g., present in n-BuLi, s-BuLi, etc.), from use of an acylation or alkylation reagent (e.g., fragments such as acyl or optionally substituted alkanoyl, such as formyl, acetyl, benzoyl, methyl, ethyl, etc.), from use of a conjugated alkylene monomer (e.g., such as a quinone methide monomer), or from use of an alcohol termination agent (e.g., fragments such as optionally substituted alkoxy). The end groups can include any useful binding group or a reactive group (e.g., those including optionally substituted trialkylsiloxy, optionally substituted alkenyl, optionally substituted aryl, etc.).

The SRP can include a poly(phthalaldehyde) or a derivative thereof, which can be a polymer that is linear or cyclic. In one embodiment, the SRP is or includes a structure of formula (I):

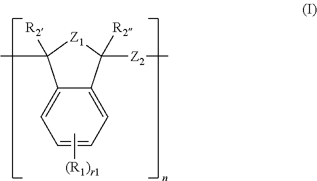

or a salt thereof, wherein
each R₁ is, independently, H, optionally substituted alkyl, optionally substituted alkoxy, optionally substituted alkenyl, optionally substituted aryl, or halo;
each of R_{2′} and R_{2″} is, independently, H, optionally substituted alkyl, optionally substituted heteroalkyl, or optionally substituted aryl;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (I)), each of R_{2′} and R_{2″} is, independently, H or optionally substituted alkyl. In some embodiments, each of Z₁ and Z₂ is —O—. In other embodiments, at least one of R₁, R_{2′}, or R_{2″} includes a metal-binding moiety (e.g., any described herein).

The SRP can include a poly(aldehyde) or a derivative thereof, which can be a polymer that is linear or cyclic. In one embodiment, the SRP is or includes a structure of formula (II):

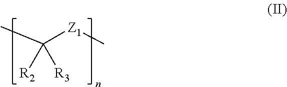

or a salt thereof, wherein:
each of R₂ and R₃ is, independently, H, optionally substituted alkyl, optionally substituted heteroalkyl, or optionally substituted aryl;
Z₁ is —O—, —S—, or optionally substituted heteroalkylene; and
n is from about 2 to about 100,000.
   In some embodiments, at least one of R₂ or R₃ includes a metal-binding moiety (e.g., any described herein).

The SRP can include a poly(benzyl carbamate) or a derivative thereof, which can be a polymer that is linear or cyclic. In one embodiment, the SRP is or includes a structure of formula (III):

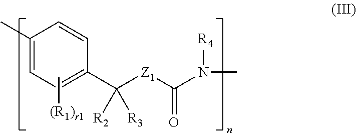

or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
R₄ is H or optionally substituted alkyl;
Z₁ is —O—, —S—, or optionally substituted heteroalkylene;
r1 is an integer from 1 to 4; and
n is from about 2 to about 100,000.

In particular embodiments (e.g., of formula (III)), R₁ is optionally substituted alkoxy. In other embodiments, n is from about 2 to about 100 (e.g., from about 2 to 10, 2 to 15, 2 to 20, 2 to 25, 2 to 30, 2 to 40, 2 to 50, 2 to 75, 4 to 10, 4 to 15, 4 to 20, 4 to 25, 4 to 30, 4 to 40, 4 to 50, 4 to 75, and 4 to 100). In other embodiments, at least one of R₁, R₂, R₃, or R₄ includes a metal-binding moiety (e.g., any described herein).

The SRP can include a poly(benzyl ether) or a derivative thereof, which can be a polymer that is linear or cyclic. In one embodiment, the SRP is or includes a structure of formula (IV):

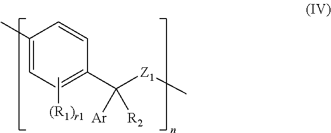

or a salt thereof, wherein:
each R₁ is, independently, H, optionally substituted alkyl, optionally substituted alkoxy, optionally substituted alkenyl, optionally substituted aryl, or halo;
R₂ is H, optionally substituted alkyl, optionally substituted heteroalkyl, or optionally substituted aryl;
Ar is optionally substituted aryl, optionally substituted alkyl, or optionally substituted aralkyl;
Z₁ is —O—, —S—, or optionally substituted heteroalkylene;
r1 is an integer from 1 to 4; and
n is from about 2 to about 100,000.

In particular embodiments (e.g., of formula (IV)), R₁ is optionally substituted alkyl. In other embodiment, Ar is optionally substituted phenyl. In other embodiments, n is from about 2 to about 5000. In other embodiments, at least one of R₁, R₂, or Ar includes a metal-binding moiety (e.g., any described herein).

The SRP can include a poly(benzyl dicarbamate) or a derivative thereof, which can be a polymer that is linear or cyclic. In one embodiment, the SRP is or includes a structure of formula (V):

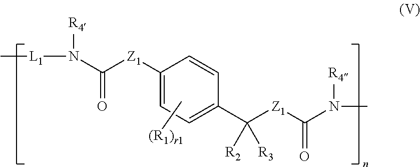

a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
each of R_{4′} and R_{4″} is, independently, H or optionally substituted alkyl;
L₁ is optionally substituted alkylene, optionally substituted heteroalkylene, optionally substituted arylene, or optionally substituted cycloalkylene;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (V)), R₁ is optionally substituted alkyl. In other embodiment, Ar is optionally substituted phenyl. In other embodiments, n is from about 2 to about 5000. In other embodiments (e.g., of formula (V)), each of R_{4′} and R_{4″} is, independently, optionally substituted alkyl. In some embodiments, L₁ is optionally substituted alkylene. In other embodiments, Z₁ and Z₂ is —O—. In other embodiments, at least one of R₁, R₂, R₃, R_{4′}, or R_{4″} includes a metal-binding moiety (e.g., any described herein).

The SRP can include a poly(dicarbamate) or a derivative thereof, which can be a polymer that is linear or cyclic. In one embodiment, the SRP is or includes a structure of formula (VI):

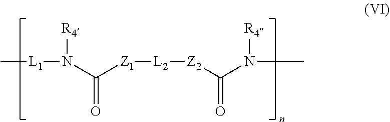

or a salt thereof, wherein:
each of R_{4′} and R_{4″} is, independently, H or optionally substituted alkyl;
each of L₁ and L₂ is, independently, optionally substituted alkylene, optionally substituted heteroalkylene, optionally substituted arylene, or optionally substituted cycloalkylene, in which L₂ can optionally be a covalent bond;
each of Z₁ and Z₂ is, independently, —O—, —S—, or optionally substituted heteroalkylene; and
n is from about 2 to about 100,000.

In particular embodiments (e.g., of formula (VI)), each of R_{4′} and R_{4″} is, independently, optionally substituted alkyl. In some embodiments, each of L₁ and L₂ is, independently, optionally substituted alkylene. In other embodiments, each of Z₁ and Z₂ is, independently, —O— or —S—. In yet other embodiments, Z₁ and Z₂ is —O—. In other embodiments, at least one of L₁, L₂, R_{4′}, or R_{4″} includes a metal-binding moiety (e.g., any described herein).

The SRP can include a poly(alpha-methyl styrene) or a derivative thereof, which can be a polymer that is linear or cyclic. In one embodiment, the SRP is or includes a structure of formula (VII):

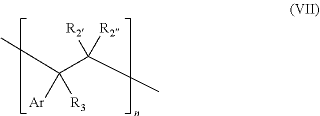

or a salt thereof, wherein:
each of R_{2′}, R_{2″}, and R₃ is, independently, H, optionally substituted alkyl, optionally substituted heteroalkyl, or optionally substituted aryl;
Ar is optionally substituted aryl, optionally substituted alkyl, or optionally substituted aralkyl; and
n is from about 2 to about 100,000.
   In other embodiments, at least one of Ar, R_{2′}, R_{2″}, or R₃ includes a metal-binding moiety (e.g., any described herein).

The SRP can include a poly(carbonate) or a derivative thereof, which can be a polymer that is linear or cyclic. In one embodiment, the SRP is or includes a structure of formula (VIII):

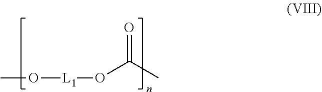

or a salt thereof, wherein:
L₁ is optionally substituted alkylene, optionally substituted heteroalkylene, optionally substituted arylene, or optionally substituted cycloalkylene; and
n is from about 2 to about 100,000.

In particular embodiments (e.g., of formula (VIII)), L₁ is optionally substituted alkylene, optionally substituted heteroalkylene, or optionally substituted cycloalkylene. In some embodiments, the optionally substituted heteroalkylene is —X-Ak-X—, in which X is oxy and Ak is optionally substituted alkylene. In other embodiments, L₁ includes a metal-binding moiety (e.g., any described herein). Non-limiting SRPs can include poly(ethylene carbonate), poly(propylene carbonate) (PPC), poly(butylene carbonate) (PBC), poly(cyclohexene carbonate) (PCHC), poly(norbornene carbonate) (PNC), and poly(cyclohexene propylene carbonate) (PCPC).

The SRP can include a poly(norbornene) or a derivative thereof, which can be a polymer that is linear or cyclic. In one embodiment, the SRP is or includes a structure of formula (IX):

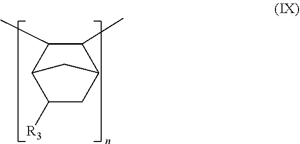

or a salt thereof, wherein:
R₃ is H, optionally substituted alkyl, optionally substituted heteroalkyl, or optionally substituted aryl; and
n is from about 2 to about 100,000.
   In other embodiments, R₃ includes a metal-binding moiety (e.g., any described herein).

The SRP can include a poly(olefin sulfone) or a derivative thereof, which can be a polymer that is linear or cyclic. In one embodiment, the SRP is or includes a structure of formula (X):

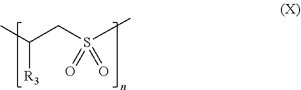

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (X)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl). In other embodiments, R₃ includes a metal-binding moiety (e.g., any described herein).

The SRP can include a poly(glyoxylate) or a derivative thereof, which can be a polymer that is linear or cyclic. In one embodiment, the SRP is or includes a structure of formula (XI):

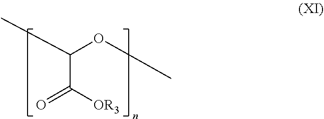

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (XI)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{Ol}, R^{N1}, and R^{N2} is, independently, H or optionally substituted alkyl. In other embodiments, R₃ includes a metal-binding moiety (e.g., any described herein).

The SRP can include a poly(methyl methacrylate) or a derivative thereof, which can be a polymer that is linear or cyclic. In one embodiment, the SRP is or includes a structure of formula (XII):

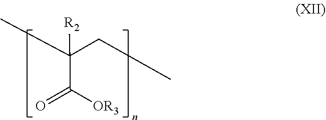

or a salt thereof, wherein:
each of R₂ and R₃ is, independently, H, optionally substituted alkyl, optionally substituted heteroalkyl, or optionally substituted aryl; and
n is from about 2 to about 100,000.

In particular embodiments (e.g., of formula (XII)), R₂ is optionally substituted alkyl. In other embodiments (e.g., of formula (XII)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl. In other embodiments, at least one of R₂ or R₃ includes a metal-binding moiety (e.g., any described herein).

The SRP can include a poly(glyoxylamide) or a derivative thereof, which can be a homopolymer that is linear or cyclic. In one embodiment, the SRP is or includes a structure of formula (XIII):

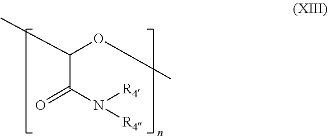

or a salt thereof, wherein:
each of R_{4′} and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein; and
n is from about 2 to about 100,000.

In particular embodiments (e.g., of formula (XIII)), each of R_{4′} and/or R_{4″} is optionally substituted alkyl, optionally substituted heteroalkyl, or optionally substituted aminoalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R_{N1}, and R^{N2} is, independently, H or optionally substituted alkyl. In other embodiments, R_{4′} is H or alkyl, and R_{4″} is optionally substituted alkyl, optionally substituted heteroalkyl, or optionally substituted aminoalkyl (e.g., as described above). In yet other embodiment, R_{4′}, and R_{4″}, taken together with the nitrogen atom to which each are attached, form a heterocyclyl group, as defined herein. Non-limiting heterocyclyl groups include pyrrolidinyl, piperidinyl, morpholinyl, oxazolyl, isoxazolyl, pyrrolyl, pyrazolyl, and the like.

As can be seen in formula (I) and (II), the SRP can be a poly(aldehyde), including poly(phthalaldehyde) or a generic poly(aldehyde) with a backbone consisting of alternating carbon and oxygen, including poly(oxymethylene). Such SRPs can be a linear or a cyclic polymer. The SRP can be a poly(phthalaldehyde) or a derivative thereof, such as a polymer including a structure of formula (Ia):

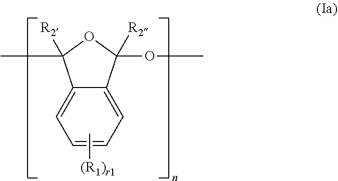

or a salt thereof, for any R₁, R_{2′}, R_{2″}, r1, and n described herein. In some instances, n is an integer from 4 to 100,000. In other embodiments, at least one of R₁, R_{2′}, or R_{2″} includes a metal-binding moiety (e.g., any described herein).

In other embodiments, the poly(phthalaldehyde) is cyclic. In some instances, the polymer has structure of formula (Ib) or (Ic):

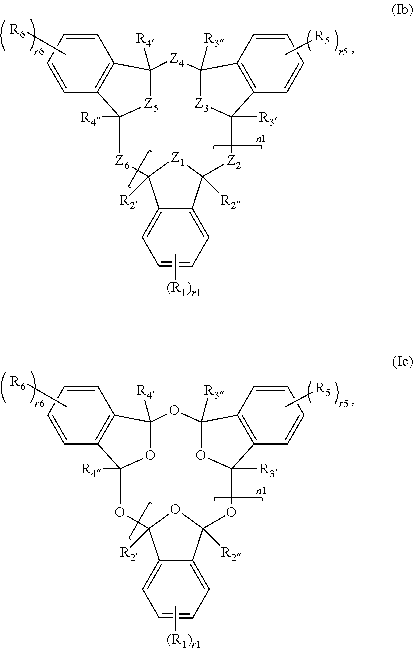

or a salt thereof, or any R₁, R₅, R₆, R_{2′}, R_{2″}, R_{3′}, R_{3″}, R_{4′}, R_{4″}, Z₁, Z₂, Z₃, Z₄, Z₅, Z₆, r1, r5, r6, and n1 described herein. In some instances, n1 is an integer from 1 to 100. In other embodiments, at least one of R₁, R₅, R₆, R_{2′}, R_{2″}, R_{3′}, R_{3″}, R_{4′}, or R_{4″} includes a metal-binding moiety (e.g., any described herein).

In any embodiment herein (e.g., in formula (I)-(VI) and (Ib)), each of Z₁ to Z₆, L₁, and L₂, if present, is, independently, an optionally substituted heteroalkylene selected from —CR₂R₃O—, —OCR₂R₃—, —OCR₂R₃O—, —(CR₂R₃S)ₕ₁CR₂R₃—, —S(CR₂R₃S)ₕ₁—, —CR₂R₃S—, —SCR₂R₃—, —SCR₂R₃S—, —(CR₂R₃S)ₕ₁CR₂R₃—, and —S(CR₂R₃S)ₕ₁—, in which each of R₂ and R₃ is, independently, H, optionally substituted alkyl, or optionally substituted aryl, and h1 is an integer from 1 to 5. In other embodiments, each of Z₁ to Z₆, L₁, and L₂, if present, is, independently, —O— or an optionally substituted heteroalkylene.

In any embodiment herein (e.g., in formula (I)-(V), (VII), and (XII)), each of R₂, R_{2′}, and R_{2″}, if present, is, independently, H or optionally substituted alkyl (e.g., C₁₋₆ alkyl).

In any embodiment herein (e.g., in formula (II), (III), (V), (VII), (IX), (X), (XI), and (XII)), R₃ is optionally substituted aryl.

In any embodiment herein (e.g., in formula (II), (III), (V), (VII), (IX), (X), (XI), and (XII)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

In any embodiment herein, the polymer is a homopolymer or a copolymer. Such a polymer can have any useful number n of monomers, such as n is from about 2 to about 100,000 (e.g., about 2 to 50, 2 to 100, 2 to 200, 2 to 300, 2 to 400, 2 to 500, 2 to 1,000, 2 to 2,000, 2 to 5,000, 2 to 10,000, 2 to 20,000, 2 to 50,000, 2 to 100,000, 3 to 50, 3 to 100, 3 to 200, 3 to 300, 3 to 400, 3 to 500, 3 to 1,000, 3 to 2,000, 3 to 5,000, 3 to 10,000, 3 to 20,000, 3 to 50,000, 3 to 100,000, 4 to 50, 4 to 100, 4 to 200, 4 to 300, 4 to 400, 4 to 500, 4 to 1,000, 4 to 2,000, 4 to 5,000, 4 to 10,000, 4 to 20,000, 4 to 50,000, 4 to 100,000, 5 to 50, 5 to 100, 5 to 200, 5 to 300, 5 to 400, 5 to 500, 5 to 1,000, 5 to 2,000, 5 to 5,000, 5 to 10,000, 5 to 20,000, 5 to 50,000, 5 to 100,000, 10 to 50, 10 to 100, 10 to 200, 10 to 300, 10 to 400, 10 to 500, 10 to 1,000, 10 to 2,000, 10 to 5,000, 10 to 10,000, 10 to 20,000, 10 to 50,000, 10 to 100,000, 50 to 100, 50 to 200, 50 to 300, 50 to 400, 50 to 500, 50 to 1,000, 50 to 2,000, 50 to 5,000, 50 to 10,000, 50 to 20,000, 50 to 50,000, 50 to 100,000, 100 to 200, 100 to 300, 100 to 400, 100 to 500, 100 to 1,000, 100 to 2,000, 100 to 5,000, 10 to 10,000, 100 to 20,000, 100 to 50,000, and 100 to 100,000). In other embodiments, the polymer is cyclic, in which n is from about 3 to about 100. In other embodiments, the cyclic polymer includes any useful number n1+2 of monomers, such as n1 from about 1 to about 100.

In particular embodiments, the SRPs may also be any appropriate linear or cyclic copolymer including the pure phthalaldehyde homopolymer, a homopolymer of poly(phthalaldehyde) derivatives such as poly(4,5-dichlorophthalaldehyde), or a homopolymer of poly(aldehyde) derivatives. SRPs can include a copolymer including a structure of one of formulas (I)-(XIII), (Ia), (Ib), (Ic), or a salt thereof, as well as any copolymer described herein (e.g., one of formulas (XIV) or (XV)).

Further example of SRPs are provided below. In some embodiments, the SRPs are copolymers including poly(aldehydes). In particular embodiments, they may be self-immolative polymers as described in U.S. Patent Publication No. 2018/0155483, which was published on Jun. 7, 2018 and which is hereby incorporated herein by reference in its entirety. Examples of copolymers in that reference include those of Formula (XIV):

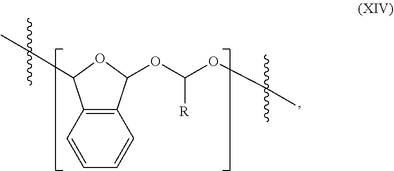

wherein: R is substituted or unsubstituted C₁₋₂₀ alkyl, C₁₋₂₀ alkoxy, C₂₋₂₀ alkenyl, C₂₋₂₀ alkynyl, C₆₋₁₀ heteroaryl, C₃₋₁₀ cycloalkyl, C₃₋₁₀ cycloalkenyl, C₃₋₁₀ heterocycloalkyl, or C₃₋₁₀ heterocycloalkenyl; and, when substituted, R is substituted with C₁₋₂₀ alkyl, C₁₋₂₀ alkoxy, C₂₋₂₀ alkenyl, C₂₋₂₀ alkynyl, C₆₋₁₀ aryl, C₆₋₁₀ heteroaryl, carboxyaldehyde, amino, sulfonic acid, sulfinic acid, fluoroacid, phosphonic acid, ether, halo, hydroxyl, ketone, nitro, cyano, azido, silyl, sulfonyl, sulfinyl, or thiol. In other embodiments, at least one R includes a metal-binding moiety (e.g., any described herein).

In particular embodiments, the SRPs are cyclic copolymers of the phthalaldehyde monomer with a second aldehyde such as ethanal, propanal, or butanal. Examples of such copolymers are given in U.S. Patent Publication No. 2018/0155483 as Formula (XV):

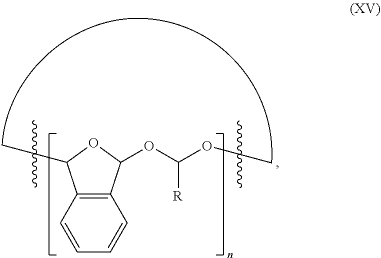

wherein n is an integer from 1 to 100,000 and R can be any described herein (e.g., such as for Formula (XIV)). In other embodiments, at least one R includes a metal-binding moiety (e.g., any described herein).

Specific examples in U.S. Patent Publication No. 2018/0155483 include copolymers of phthalaldehyde and one or more of acetaldehyde, propanal, butanal, pentanal, hexanal, heptanal, octanal, nonanal, decanal, undecanal, propenal, butenal, pentenal, hexenal, heptenal, octenal, nonenal, decenal, undecenal, and any combination thereof.

The SRPs may also be any appropriate linear or cyclic copolymer including the pure phthalaldehyde homopolymer. It also may be a homopolymer of poly(phthalaldehyde) derivatives such as poly(4,5-dichlorophthalaldehyde).

In any embodiment herein, the SRP includes a monomer that is or has a structure of any of formulas (I)-(XV), (Ia), or a salt thereof, in which n is 1, which is then linked to another monomer by way of a linker. Non-limiting linkers include optionally substituted alkylene, optionally substituted heteroalkylene, optionally substituted (aryl)(alkyl)ene, optionally substituted arylene, optionally substituted cycloalkylene, oxy, or thio. In other embodiments, the linker can be -Ak-, -Ak-X—, —X-Ak-, -(Ak-X)ₕ₁-Ak-, —X-(Ak-X)ₕ₁—, -Ak-Ar—, -Ak-Ar-Ak-, —Ar-Ak-, -(Ak-X)ₕ₁—Ar—, -(Ak-X)ₕ₁—Ar-(Ak-X)ₕ₁—, —Ar-(Ak-X)ₕ₁—, —X-(Ak-X)ₕ₁—Ar—, —X-(Ak-X)ₕ₁—Ar—X-(Ak-X)ₕ₁—, and —Ar—X-(Ak-X)ₕ₁—, in which Ak is an optionally substituted alkylene, Ar is an optionally substituted arylene, X is or includes a non-carbon heteroatom (e.g., —O—, —S—, or —NR^{N1}—, which R^{N1} is H, optionally alkyl, or optionally substituted aryl), and h1 is an integer from 1 to 5.

In any embodiment herein, the SRP can be an amorphous polymer that remains solvent soluble.

The SRP can be synthesized using any corresponding monomer. For instance, the monomer can be or have a structure of any of formulas (I)-(XV), (Ia), or a salt thereof, in which n is 1. The monomer can have any useful end group disposed on either end of such a structure. In other embodiments, the monomer can be volatile and possess a melting point at or below 20° C.

In particular embodiments, the SRP is formed with no unwanted side products. In this way, residue-free vaporization of the polymer can be achieved because side products need not be removed. For removal, scission of one (or few) chemical bonds within the SRP propagates full, rapid depolymerization of the polymer. Since all the bonds are the same (no inadvertent impurities), little or no residue is expected.

The SRP, or a formulation thereof, can be deposited in any useful manner. For instance, the SRP can be spin-coated or vapor deposited.

### Formulations, Including Solvents and Additives

The SRP can be provided as a formulation having a solvent or a solvent combination. In one embodiment, the formulation includes about 0.1 wt. % to about 50 wt. % of one or more SRPs (e.g., about 5 wt. % to 20 wt. %), with the balance being the solvent. Example solvents include diglyme, tetrahydrofuran, N-methyl-pyrrolidone, dimethylformamide, propylene carbonate, cyclopentanone, anisole, dichlorobenzene, and propylene glycol methyl ether acetate.

Formulations can include one or more further additives selected from an organic acid having a pKa more than or equal to 1, a photocatalyst (e.g., a photoacid generator or a photobase generator), a thermal catalyst (e.g., a thermal acid generator or a thermal base generator), a plasticizer, and/or a dye. The amount of additive can include about 0.001 wt. % to about 25 wt. % of a single additive, as well as a combination of additives in an amount of about 0.001 wt. % to about 25 wt. %.

In some embodiments, the SRP and the additive(s) (e.g., any herein) may be formulated and stored as separate solutions but mixed together at point of deposition onto the wafer, or at some point relatively shortly beforehand. In some embodiments, the SRP and additive(s) may be provided as a powder to be mixed in the solvent before spin coating. The SRP and additive (either singularly or together) may be provided with a relative wt. % of at least 5:1 SRP:additive, or at least 10:1, or 20:1.

The low T_{c} polymers can be formulated with weak acids that create stable films under ambient conditions, as well as exhibit accelerated degradation characteristics, as compared to the neat, unformulated polymer in a solvent. Specific examples of acids with this behavior include weak organic acids (e.g., having a pKa that is more than or equal to 1). Yet other acids include tartaric acid, oxalic acid, and acetic acid.

Other examples include linear alkyl carboxylic acids, C_{X}H_{2X}O₂, where X is an integer, and the corresponding dicarboxylic acid variants. Particular examples include including methanoic acid (X=1) and acetic acid (X=2). Particular examples of dicarboxylic acids include ethanedioic acid and propanedioic acid. The organic weak acid may also be variants of any of these with additional alcohol substitutions and/or unsaturated bonds. For example, oxoethanoic acid, 2-hydroxyethanoic acid, prop-2-enoic acid, 2-propynoic acid, 2-hydroxypropanedioic acid, oxopropanedioic acid, 2,2-dihydroxypropanedioic acid, 2-oxopropanoic acid, 2-hydroxypropanoic acid, 3-hydroxypropanoic acid, 2,3-dihydroxypropanoic acid, etc., may be used.

Yet other organic acids could exhibit similar abilities. The low T_{c} polymer may be pre-formulated with the appropriate acid prior to tool installation, and then spin-coated onto the substrates for sacrificial bracing or surface protection applications. Alternatively, the low T_{c} polymer may be mixed with the acid at point of use, right before spin-coating. This approach may be used to prolong the shelf-life of the polymer formulation, since although it is stable in film form (solid state), it may not be stable in solution once contacted with the acid. In some embodiments, the formulation is provided as about 5-20 wt. % SRP and <1 wt. % organic weak acid, with the balance being the solvent.

The formulation, and thus the resultant film, can include a photoacid generator (PAG), in which exposure of the SRP to electromagnetic radiation produces acid. In this way, energetic light (e.g., UV light, IR lights, or x-rays) exposure generates acid to promote in situ degradation of the film. Non-limiting photoacid generators include onium salts, such as iodonium and sulfonium salts having perfluorinated anions (e.g., diaryliodonium and triarylsulfonium salts), bissulfonyldiazomethane compounds, N-sulfonyloxydicarboximide compounds, and O-arylsulfonyloxime compounds. The photoacid generator may optionally include a photosensitizer (e.g., having modified polyaromatic hydrocarbons or fused aromatic rings).

Other acid generators can be used, such as a thermal acid generator that releases acidic moieties upon exposure to heat. In this way, depolymerization of the SRP can include both thermal and acidic processes. Non-limiting thermal acid generators include ammonium salts, sulfonyl esters, and acid amplifiers.

Plasticizers can be employed to promote plasticity or flexibility in the film. Non-limiting plasticizers can include adipates, alkylene glycol dibenzoates, dialkyl phthalates, trialkyl trimellitates, tertiary amines, quaternary ammonium compounds, azelates, citrates, ether-esters, polyethers, glutarates, glycols, isobutyrates, maleates, phosphates, phosphonium compounds, organophosphates, sebacates, sulfonamides, sulfonium compounds, as well as ionic liquids, surfactants, and acid amplifiers, or a combination thereof.

### Removal of SRPs

Several methods have been developed to achieve residue-free removal of SRPs without modifying the sensitive substrates. One method for depolymerizing the material includes exposing the polymer to elevated temperature under vacuum conditions. This method can lead to a rapid volatilization of the polymer, however angstrom-level residues, composed of char and residual monomer, often remain on the surface.

SRPs can be removed by using a less aggressive trigger, such as light or mild temperatures. These sacrificial polymers could allow protection of the sensitive surfaces and subsequent removal of the barrier film without exposing the surfaces to aggressive plasmas or wet chemical solutions. For certain challenging applications, there may be limitations to the temperature at which the substrates can be exposed, or extremely stringent contamination or throughput requirements. The SRPs and films thereof can be designed to address these applications.

Non-limiting removal conditions also include exposure to acidic or basic vapors. Such vapors can be provided by a reactant, such as an acid (e.g., having a pKa of less than 7, and in some embodiments less than 4, or less than 2) or a base (e.g., having a pKb of less than 7, and in some embodiments, less than 4 or less than 2). Non-limiting reactants include sulfurous acid, formic acid, nitric acid, carbonic acid, or ammonium hydroxide.

Other non-limiting acid/base catalysts include hydrogen bromide (HBr), hydrogen chloride (HCl), hydrogen fluoride (HF), hydrogen iodide (HI), nitric acid (HNO₃), formic acid (CH₂O₂), acetic acid (CH₃COOH), formonitrile (HCN), sulfurous acid (H₂SO₃), carbonic acid (H₂CO₃), nitrous acid (HNO₂), or ammonia (NH₃), and methyl or ethyl amine gas or vapor may be used. In some examples, when HBr vapor is used, the substrate is maintained at a pressure in a range from 1 mTorr to 5000 mTorr (e.g., from 5 mTorr to 5000 mTorr) and a temperature in a range from 0° C. to 200° C. (e.g., from 0° C. to 100° C.). In some examples, the substrate is maintained at a pressure in a range from 750 mTorr to 1500 mTorr and a temperature in a range from 35° C. to 70° C. In some examples, the temperature of the substrate is maintained at a pressure of 1000 mTorr and a temperature of 60° C. The amount of acidic vapor or vapor of other compound is controlled to limit the diffusion. Exposure time can depend on the strength of the acid or base, as well as film thickness and exposure temperature (e.g., from about 20° C. to about 125° C. or from about 100° C. to about 125° C.). Non-limiting exposure time can include less than about 60 seconds or on the order of minutes.

In other embodiments, removal can include exposure to two reactants that react to form an acid or base that can trigger the degradation of the SRP. The exposure occurs sequentially to provide more precise top down control. In some embodiments, the methods involve diffusing a compound, or a reactant that reacts to form a compound, only to a top portion of the SRP. The top portion is then degraded and removed, leaving the remaining SRP intact. The exposure and removal cycles can be repeated. Optionally, a purge operation can follow the exposure operation to remove the compound or reactant from the chamber.

Non-limiting reactants (e.g., to form an acid or base) can include water vapor with one of ammonia (NH₃) or a gaseous oxide, which reacts with the water vapor to an acidic or basic species. For instance, NH₃ and water can react to form ammonium hydroxide (NH₄OH). Examples of gaseous oxides include nitrogen dioxide (NO₂, which can react with water to form nitric acid, HNO₃), sulfur dioxide (SO₂, which can react with water to form sulfurous acid, H₂SO₃), and carbon dioxide (CO₂, which can react with water to form carbonic acid, H₂CO₃). Other oxides may react with water or another reactant to form acids or bases.

Alternative polymer removal processes can provide lower contamination levels. In one such process, the polymer is exposed to long-lived metastable species from a noble gas plasma under vacuum at elevated temperature. In another process, the polymer is exposed to infrared (IR), ultraviolet (UV), or extreme UV radiation at elevated temperature while under vacuum. Other processes include high temperature exposure (e.g., about 50° C. to about 250° C.) under vacuum conditions (e.g., <760 Torr) for a limited exposure time. Another process can include simultaneous high temperature exposure and radiation exposure by either UV or IR, which are under vacuum. Yet another process can include simultaneous high temperature exposure and noble gas metastable exposure, which are under vacuum. In particular embodiments, these removal processes have also shown low contamination without increasing the surface modification of the sensitive substrates.

Within a chamber, the substrate can be exposed to heat for SRP removal. Heat can be provided as a constant temperature hold. Alternatively, heat can be provided as a ramped temperature, in which increasing or decreasing temperature ramping can be used between temperature holds. Such thermal energy can provide sufficient energy to depolymerize the SRP by providing heat at a temperature that is above the T_{c}. Such conditions can include exposure to a temperature of up to 250° C. for an SRP having a T_{c} that is below 250° C., in which the SRP is kinetically trapped below the T_{c}. In other embodiments, thermal exposure can include a temperature from about 50° C. to about 250° C. (e.g., about 50° C. to 150° C., 50° C. to 250° C., 150° C. to 200° C., 150° C. to 250° C., or 200° C. to 250° C., etc.). In other embodiments, thermal exposure includes exposure to an elevated temperature (e.g., up to 800° C.) with a fast ramp rate and a shorter time. When additives (e.g., a photoacid generator (PAG) or any herein) are used, the temperature for removal can be between about 50° C. and about 125° C., in addition to exposure to other stimulus that can beneficially activate the additive (e.g., UV exposure to activate the PAG).

For basic thermal removal of surface protection films (e.g., providing a substrate on a hot plate), exposure time can be from about 20 seconds to about 400 seconds (e.g., about 30 to 300 seconds). Thicker films can require longer exposure to heat for SRP removal, as compared to thinner films. Film thickness required will be application dependent. For instance, some removal thermal processes (e.g., using a rapid thermal processor (RTP)) can include higher temperatures (e.g., more than about 400° C.) for very short times (e.g., one to two seconds of exposure for RTP, as well as millisecond exposure times for flash lamp type processes). For applications that are thermal budget sensitive, RTP-type conditions can be employed, whereas other processes may employ a hot plate under vacuum.

Alternatively, the SRP can be removed by exposure to radiation (e.g., UV radiation or IR radiation), either with or without vacuum. In some instances, process conditions include exposure to about 200° C. under vacuum at about 2.5 W/cm² UV dose rate. In other instances, process conditions (e.g., for an SRP employed with a photoacid generator) includes exposure to about 110° C. under vacuum for at about 0.05 mW/cm² UV dose rate. In any of these process conditions, exposure can include from about 100 seconds to about 400 seconds (e.g., about 300 seconds).

For radiation removal of surface protection films (e.g., pure SRP), exposure time can be from about 20 seconds to about 400 seconds (e.g., about 30 to 300 seconds). Thicker films can require longer exposure to radiation (e.g., UV) for SRP removal, as compared to thinner films. Film thickness required will be application dependent. For films with acid generating additives (e.g., PAG), the exposure times may range from two minutes to ten minutes. Exposure time can depend on many conditions, including the loading of the additives, wafer temperature, UV dose rate, and film thickness. These requirements, in turn, will be application dependent (e.g., depend on feature dimensions, aspect ratio, pattern density, etc.).

Radiation dosage can be, e.g., from about 0.1 mW/cm² to about 15 W/cm² for UV. For collapse sensitive applications in which rate control of the degradation can be desired, lower dose rates can be employed, e.g., from about 0.01 to about 0.07 mW/cm². For pure SRP film removal from blanket surfaces, higher dose rates can be employed, e.g., about 2.5 W/cm². Generally, the higher the dose rate, the cleaner the removal. Of course, radiation exposure can also be application dependent, and excessive radiation can be avoided to mitigate substrate damage.

During radiation exposure, the substrate can be maintained at an elevated temperature (e.g., from about 50° C. to about 250° C., including about 200° C.). When the formulation includes acid generating additives (e.g., PAG), then lower temperatures can be combined with UV exposure to provide a controlled degradation rate (e.g., temperature range of about 50° C. to about 125° C. or from about 100° C. to about 110° C.).

Metastable atoms can be employed. The metastable atoms can be generated from a noble gas plasma to provide an excited state, the noble gas being one or more of helium (He), neon (Ne), argon (Ar), krypton (Kr), and xenon (Xe), to remove residue from the substrate. In some embodiments, the metastable species are not chemically reactive and do not appreciably affect the underlying surface. The metastable species from the noble gas plasma can be effective at removing residues that remain after exposure to other stimuli such as heat. In the methods described herein, removing SRPs includes exposure to high energy metastable species, generated in a noble gas plasma, at an elevated temperature. The metastable species have sufficient energies and lifetimes to scission bonds on the polymer or other residues. At temperatures greater than the ceiling temperature, there is a strong thermodynamic driving force to revert to volatile monomers once bond scissioning has occurred. The metastable species are not chemically reactive and do not appreciably affect the underlying surface. The metastable species are effective at removing residue that remains after exposure to other stimuli such as heat. This residue may be some SRP that remains polymerized or cross-linked and/or carbonized shards that is detectable by ellipsometry. While most of the SRP can be removed by the stimuli described above, this residue can be difficult to fully remove by those methods. Without being bound by a particular theory, the metastables may remove residues by re-initiating chain scissioning that may have stopped prematurely due to side product formation, by breaking down char that may have formed during the depolymerization process, and by aiding monomer desorption.

In some embodiments, most of the SRP is removed before exposing the substrate to the metastable atoms. In some embodiments, the substrate is exposed to the metastable atoms before most of the SRP is removed. In some embodiments, the plasma pressure is between about 10 mTorr to 10 Torr. In some embodiments, the plasma pressure is between about 100 mTorr and 1 Torr. In some embodiments, the SRP is provided as a protective coating on substrate. In some embodiments, the plasma is generated in an inductively coupled plasma (ICP) source. In some such embodiments, the ICP source is separated from the substrate by a showerhead or other filter. In some embodiments, the plasma is generated in capacitively coupled plasma (CCP) source. Any other type of plasma source may be used. In some embodiments, exposing the substrate to a stimulus and exposing the substrate to the metastable atoms are performed in the same chamber.

Processing and plasma source chamber pressure may be used to control the plasma-based removal. Pressure is important to control the density of the metastable atoms. If pressure is too low, the density of metastable atoms may not be high enough to efficiently clean the surface. If the pressure is too high, metastable species may be lost to collisions. Example pressures may range from 10 mTorr to 10 Torr, 100 mTorr to 1 Torr, 100 mTorr to 700 mTorr, 200 mTorr to 1 Torr, or 200 mTorr to 2 Torr.

Substrate temperature and plasma power may also be used to control removal. Temperature is high enough such that it is above the ceiling temperature of the polymer. Higher temperatures aid removal with the maximum temperature limited by the thermal budget of the device or other materials on the substrate. Example temperatures may range from 150° C. to 1000° C. or from 150° C. to 250° C. Plasma power is high enough to generate metastable atoms. Example powers may range from 500 W to 5000 W or from 800 W to 5000 W, e.g., 2500 W for a 300 mm wafer, and scale linearly with substrate area. Example exposure times may range from 10 seconds to 300 seconds or from 10 seconds to 180 seconds.

Removal can occur in a single step or in a plurality of steps. A non-limiting method can include providing a substrate with an SRP film. Then, a stimulus that degrades SRP is pulsed in the chamber. Such stimulus can include exposure to a compound (e.g., an acid, a base, a compound that forms an acid or base, plasma, metastable compounds, etc.) or a reaction condition (e.g., UV radiation, IR radiation, heat, etc.). In some embodiments, removal includes exposure to heat and/or radiation, thus eliminating the need for plasma and/or harsh wet chemistries that will modify the sensitive surfaces that need to be protected.

When a compound is used, the partial pressure of the vapor and/or the pulse time can be controlled to control the overall exposure to the vapor and the diffusion depth. The chamber can be purged. Purging can involve evacuating the chamber and/or flowing inert gas to be swept out through the chamber. Such a gas may be, for example, continuously or may be itself pulsed into the chamber. Volatilized monomer or SRP fragment may be pumped or purged out of the chamber, which can be repeated until the SRP is removed. As indicated above, in some embodiments, the SRP is exposed to reactants sequentially in each cycle. This can provide additional control over the process and may be implemented in various ways.

According to various embodiments, the reaction may be catalyzed or uncatalyzed. In some embodiments, a catalyst (e.g., a thermally activated catalyst) may be provided in the SRP, delivered with a reactant, or introduced as a separate pulse. However, in many embodiments, the reaction is uncatalyzed such that SRP is provided free of catalysts. This can facilitate SRP removal. In some embodiments, the reaction is byproduct-free.

Additional examples of SRPs and methods using SRPs are described in U.S. Pat. Nos. 9,466,511, 9,666,427, 10,008,396, and 10,068,781, each of which are incorporated herein by reference in its entirety.

### Apparatus

The metal features described may be formed using the electroplating or electrodeposition processes and apparatuses herein. Such electroplating or electrodeposition apparatuses can be used in conjunction with one or more additional substrate processing tools used to process substrates, including for deposition of SRPs, removal of SRPs, alignment of metal features, bonding of metal features, and other upstream and downstream processing. In other embodiments, the electroplating or electrodeposition apparatuses can be adapted to deposit SRP within the process chamber, thereby capping metal features after deposition.

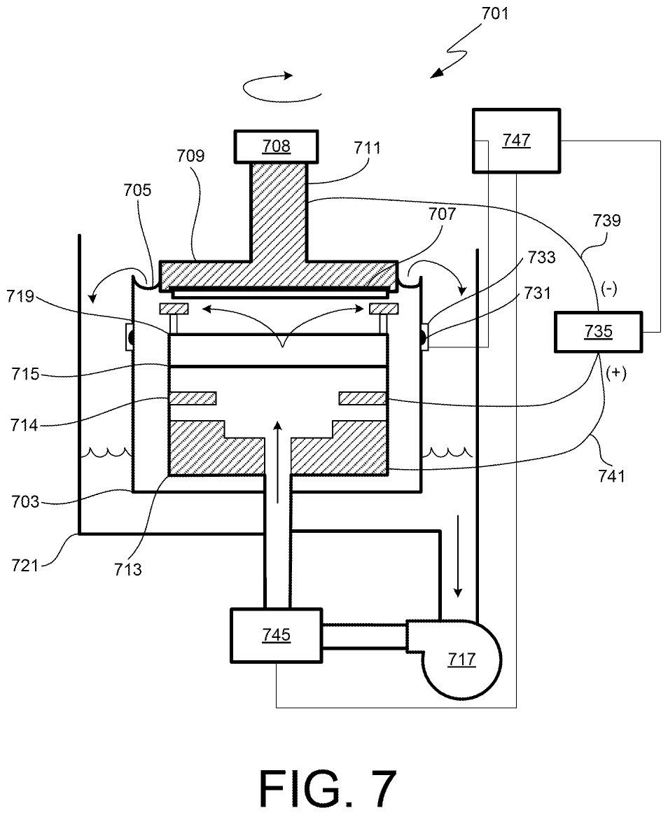

FIG. 7 presents an example of an electroplating cell in which electroplating may occur. Often, an electroplating apparatus includes one or more electroplating cells in which the substrates (e.g., wafers) are processed. Only one electroplating cell is shown in FIG. 7 to preserve clarity. To optimize bottom-up electroplating, additives (e.g., accelerators, suppressors, and levelers) are added to the electrolyte; however, an electrolyte with additives may react with the anode in undesirable ways. Therefore anodic and cathodic regions of the plating cell are sometimes separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

Referring to FIG. 7, a diagrammatical cross-sectional view of an electroplating apparatus 701 in accordance with one embodiment is shown. The plating bath 703 contains the plating solution (having a composition as provided herein), which is shown at a level 705. The catholyte portion of this vessel is adapted for receiving substrates in a catholyte. A wafer 707 is immersed into the plating solution and is held by, e.g., a “clamshell” substrate holder 709, mounted on a rotatable spindle 711, which allows rotation of clamshell substrate holder 709 together with the wafer 707. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated herein by reference in their entireties.

An anode 713 is disposed below the wafer within the plating bath 703 and is separated from the wafer region by a membrane 715, preferably an ion selective membrane. For example, Nafion™ cationic exchange membrane (CEM) may be used. The region below the anodic membrane is often referred to as an “anode chamber.” The ion-selective anode membrane 715 allows ionic communication between the anodic and cathodic regions of the plating cell, while preventing the particles generated at the anode from entering the proximity of the wafer and contaminating it. The anode membrane is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated herein by reference in their entireties. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating, the ions from the plating solution are deposited on the substrate. The metal ions must diffuse through the diffusion boundary layer and into the through silicon via (TSV) hole, opening, or other feature. A typical way to assist the diffusion is through convection flow of the electroplating solution provided by the pump 717. Additionally, a vibration agitation or sonic agitation member may be used as well as wafer rotation. For example, a vibration transducer 708 may be attached to the clamshell substrate holder 709.

The plating solution is continuously provided to plating bath 703 by the pump 717. Generally, the plating solution flows upwards through an anode membrane 715 and a diffuser plate 719 to the center of wafer 707 and then radially outward and across wafer 707. The plating solution also may be provided into the anodic region of the bath from the side of the plating bath 703. The plating solution then overflows the plating bath 703 to an overflow reservoir 721. The plating solution is then filtered (not shown) and returned to pump 717 completing the recirculation of the plating solution. In certain configurations of the plating cell, a distinct electrolyte is circulated through the portion of the plating cell in which the anode is contained, while mixing with the main plating solution is prevented using sparingly permeable membranes or ion selective membranes.

A reference electrode 731 is located on the outside of the plating bath 703 in a separate chamber 733, which chamber is replenished by overflow from the main plating bath 703. Alternatively, in some embodiments the reference electrode is positioned as close to the substrate surface as possible, and the reference electrode chamber is connected via a capillary tube or by another method, to the side of the wafer substrate or directly under the wafer substrate. In some of the preferred embodiments, the apparatus further includes contact sense leads that connect to the wafer periphery and which are configured to sense the potential of the metal seed layer at the periphery of the wafer but do not carry any current to the wafer.

A reference electrode 731 is typically employed when electroplating at a controlled potential is desired. The reference electrode 731 may be one of a variety of commonly used types such as mercury/mercury sulfate, silver chloride, saturated calomel, or copper metal. A contact sense lead in direct contact with the wafer 707 may be used in some embodiments, in addition to the reference electrode, for more accurate potential measurement (not shown).

A DC power supply 735 can be used to control current flow to the wafer 707. The power supply 735 has a negative output lead 739 electrically connected to wafer 707 through one or more slip rings, brushes and contacts (not shown). The positive output lead 741 of power supply 735 is electrically connected to an anode 713 located in plating bath 703. The power supply 735, a reference electrode 731, and a contact sense lead (not shown) can be connected to a system controller 747, which allows, among other functions, modulation of current and potential provided to the elements of electroplating cell. For example, the controller may allow electroplating in potential-controlled and current-controlled regimes. The controller may include program instructions specifying current and voltage levels that need to be applied to various elements of the plating cell, as well as times at which these levels need to be changed. When forward current is applied, the power supply 735 biases the wafer 707 to have a negative potential relative to anode 713. This causes an electrical current to flow from anode 713 to the wafer 707, and an electrochemical reduction (e.g. Cu²⁺+2e⁻=Cu⁰) occurs on the wafer surface (the cathode), which results in the deposition of the electrically conductive layer (e.g., copper) on the surfaces of the wafer. An inert anode 714 may be installed below the wafer 707 within the plating bath 703 and separated from the wafer region by the membrane 715.

The apparatus may also include a heater 745 for maintaining the temperature of the plating solution at a specific level. The plating solution may be used to transfer the heat to the other elements of the plating bath. For example, when a wafer 707 is loaded into the plating bath, the heater 745 and the pump 717 may be turned on to circulate the plating solution through the electroplating apparatus 701, until the temperature throughout the apparatus becomes substantially uniform. In one embodiment, the heater is connected to the system controller 747. The system controller 747 may be connected to a thermocouple to receive feedback of the plating solution temperature within the electroplating apparatus and determine the need for additional heating.

The controller will typically include one or more memory devices and one or more processors. The processor may include a CPU or computer, analog and/or digital input/output connections, stepper motor controller boards, etc. In certain embodiments, the controller controls all of the activities of the electroplating apparatus. Non-transitory machine-readable media containing instructions for controlling process operations in accordance with the present embodiments may be coupled to the system controller.

Typically there will be a user interface associated with controller 747. The user interface may include a display screen, graphical software displays of the apparatus and/or process conditions, and user input devices such as pointing devices, keyboards, touch screens, microphones, etc. The computer program code for controlling electroplating processes can be written in any conventional computer readable programming language: for example, assembly language, C, C++, Pascal, Fortran or others. Compiled object code or script is executed by the processor to perform the tasks identified in the program. One example of a plating apparatus that may be used according to the embodiments herein is the Lam Research Sabre tool. Electrodeposition can be performed in components that form a larger electrodeposition apparatus.

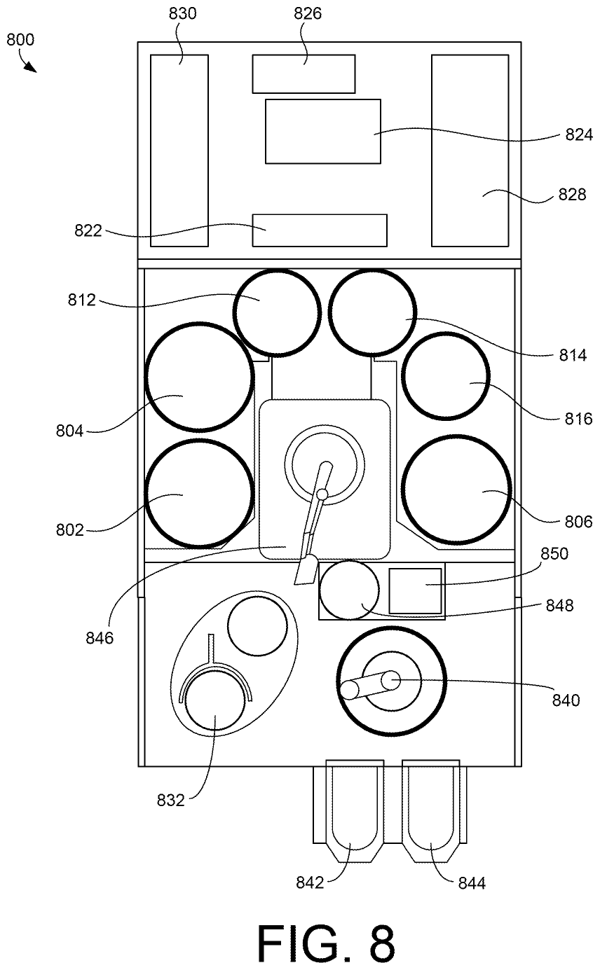

FIG. 8 shows a schematic of a top view of an example electrodeposition apparatus. The electrodeposition apparatus 800 can include three separate electroplating modules 802, 804, and 806. The electrodeposition apparatus 800 can also include three separate modules 812, 814, and 816 configured for various process operations. For example, in some embodiments, one or more of modules 812, 814, and 816 may be a spin rinse drying (SRD) module. In other embodiments, one or more of the modules 812, 814, and 816 may be post-electrofill modules (PEMs), each configured to perform a function, such as edge bevel removal, backside etching, and acid cleaning of substrates after they have been processed by one of the electroplating modules 802, 804, and 806. In another embodiment, one or more of the modules 812, 814, and 816 can be configured to deposit an SRP on a surface of the substrate after they have been processed by one of the electroplating modules 802, 804, and 806.

The electrodeposition apparatus 800 includes a central electrodeposition chamber 824. The central electrodeposition chamber 824 is a chamber that holds the chemical solution used as the electroplating solution in the electroplating modules 802, 804, and 806. The electrodeposition apparatus 800 also includes a dosing system 826 that may store and deliver additives for the electroplating solution. A chemical dilution module 822 may store and mix chemicals to be used as an etchant. A filtration and pumping unit 828 may filter the electroplating solution for the central electrodeposition chamber 824 and pump it to the electroplating modules 802, 804, and 806.

A system controller 830 provides electronic and interface controls required to operate the electrodeposition apparatus 800. The system controller 830 (which may include one or more physical or logical controllers) controls some or all of the properties of the electroplating apparatus 800. The system controller 830 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 830 or they may be provided over a network. In certain embodiments, the system controller 830 executes system control software.

The system control software in the electrodeposition apparatus 800 may include instructions for controlling the timing, mixture of electrolyte components, inlet pressure, plating cell pressure, plating cell temperature, substrate temperature, current and potential applied to the substrate and any other electrodes, substrate position, substrate rotation, and other parameters of a particular process performed by the electrodeposition apparatus 800. System control logic may be configured in any suitable way. For example, various process tool component sub-routines or control objects may be written to control operation of the process tool components necessary to carry out various process tool processes. System control software may be coded in any suitable computer readable programming language. The logic may also be implemented as hardware in a programmable logic device (e.g., an FPGA), an ASIC, or other appropriate vehicle.

In some embodiments, system control logic includes input/output control (IOC) sequencing instructions for controlling the various parameters described above. For example, each phase of an electroplating process may include one or more instructions for execution by the system controller 830. The instructions for setting process conditions for an immersion process phase may be included in a corresponding immersion recipe phase. In some embodiments, the electroplating recipe phases may be sequentially arranged, so that all instructions for an electroplating process phase are executed concurrently with that process phase.

The control logic may be divided into various components such as programs or sections of programs in some embodiments. Examples of logic components for this purpose include a substrate positioning component, an electrolyte composition control component, a pressure control component, a heater control component, and a potential/current power supply control component.

In some embodiments, there may be a user interface associated with the system controller 830. The user interface may include a display screen, graphical software displays of the apparatus and/or process conditions, and user input devices such as pointing devices, keyboards, touch screens, microphones, etc.

In some embodiments, parameters adjusted by the system controller 830 may relate to process conditions. Non-limiting examples include bath conditions (temperature, composition, and flow rate), substrate position (rotation rate, linear (vertical) speed, angle from horizontal) at various stages, etc. These parameters may be provided to the user in the form of a recipe, which may be entered utilizing the user interface.

Signals for monitoring the process may be provided by analog and/or digital input connections of the system controller 830 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

A hand-off tool 840 may select a substrate from a substrate cassette such as the cassette 842 or the cassette 844. The cassettes 842 or 844 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 840 may hold the substrate using a vacuum attachment or some other attaching mechanism.

The hand-off tool 840 may interface with a wafer handling station 832, the cassettes 842 or 844, a transfer station 850, or an aligner 848. From the transfer station 850, a hand-off tool 846 may gain access to the substrate. The transfer station 850 may be a slot or a position from and to which hand-off tools 840 and 846 may pass substrates without going through the aligner 848. In some embodiments, however, to ensure that a substrate is properly aligned on the hand-off tool 846 for precision delivery to an electroplating module, the hand-off tool 846 may align the substrate with an aligner 848. The hand-off tool 846 may also deliver a substrate to one of the electroplating modules 802, 804, or 806 or to one of the three separate modules 812, 814, or 816 configured for various process operations.

An example of a process operation according to the methods described above may proceed as follows: (1) electrodeposit copper or another material onto a substrate in the electroplating module 804; (2) rinse and dry the substrate in SRD in module 812; and (3) perform edge bevel removal in module 814. Another method includes: (1) electrodeposit copper or another material onto a substrate in the electroplating module 804; (2) rinse and dry the substrate in SRD in module 812; and (3) deposit an SRP on the substrate in module 814. Yet another method includes: (1) electrodeposit copper or another material onto a substrate in the electroplating module 804; (2) rinse and dry the substrate in SRD in module 812; (3) perform acid cleaning of the substrate in module 814; and (4) deposit an SRP on the substrate in module 816.

An apparatus configured to allow efficient cycling of substrates through sequential plating, rinsing, drying, and PEM process operations may be useful for implementations for use in a manufacturing environment. To accomplish this, the module 812 can be configured as a spin rinse dryer and an edge bevel removal chamber. With such a module 812, the substrate would only need to be transported between the electroplating module 804 and the module 812 for the copper plating and EBR operations. In some embodiments the methods described herein will be implemented in a system which comprises an electroplating apparatus and a stepper.

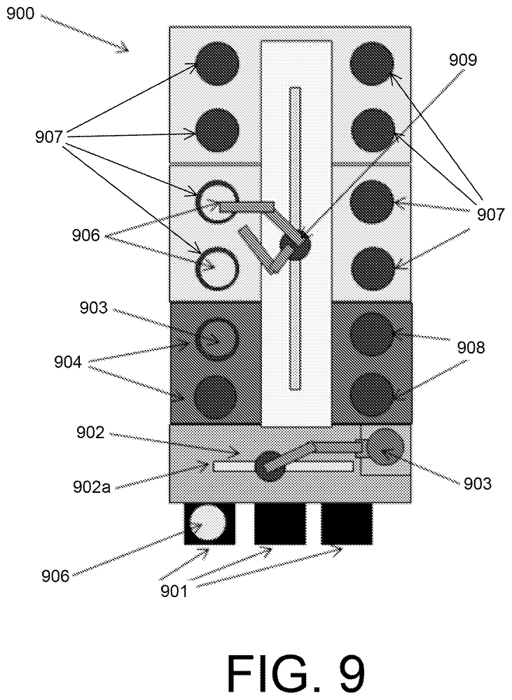

An alternative embodiment of an electrodeposition apparatus 900 is schematically illustrated in FIG. 9. In this embodiment, the electrodeposition apparatus 900 has a set of electroplating cells 907, each containing an electroplating bath, in a paired or multiple “duet” configuration. In addition to electroplating per se, the electrodeposition apparatus 900 may perform a variety of other electroplating related processes and sub-steps, such as spin-rinsing, spin-drying, metal and silicon wet etching, electroless deposition, pre-wetting and pre-chemical treating, reducing, annealing, electro-etching and/or electropolishing, photoresist stripping, and surface pre-activation, for example. The electrodeposition apparatus 900 is shown schematically looking top down in FIG. 9, and only a single level or “floor” is revealed in the figure, but it is to be readily understood by one having ordinary skill in the art that such an apparatus, e.g., the Lam Sabre™ 3D tool, can have two or more levels “stacked” on top of each other, each potentially having identical or different types of processing stations.

Referring once again to FIG. 9, the substrates 906 that are to be electroplated are generally fed to the electrodeposition apparatus 900 through a front end loading FOUP 901 and, in this example, are brought from the FOUP to the main substrate processing area of the electrodeposition apparatus 900 via a front-end robot 902 that can retract and move a substrate 906 driven by a spindle 903 in multiple dimensions from one station to another of the accessible stations—two front-end accessible stations 904 and also two front-end accessible stations 908 are shown in this example. The front-end accessible stations 904 and 908 may include, for example, pre-treatment stations, and spin rinse drying (SRD) stations. Lateral movement from side-to-side of the front-end robot 902 is accomplished utilizing robot track 902a. Each of the substrates 906 may be held by a cup/cone assembly (not shown) driven by a spindle 903 connected to a motor (not shown), and the motor may be attached to a mounting bracket 909. Also shown in this example are the four “duets” of electroplating cells 907, for a total of eight electroplating cells 907. A system controller (not shown) may be coupled to the electrodeposition apparatus 900 to control some or all of the properties of the electrodeposition apparatus 900. The system controller may be programmed or otherwise configured to execute instructions according to processes described earlier herein.

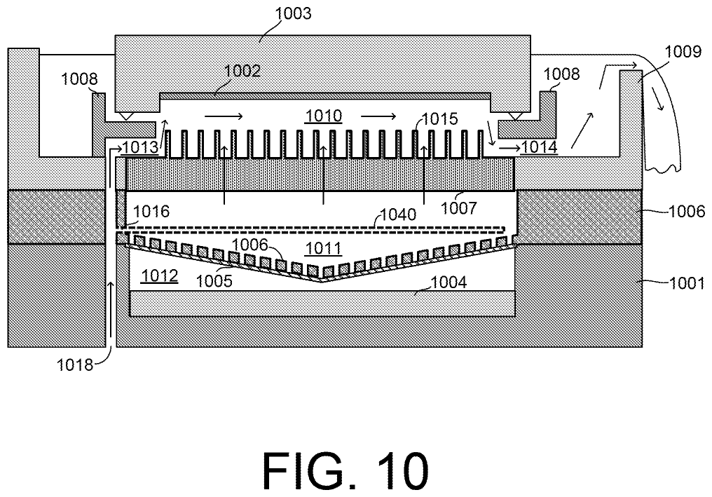

FIG. 10 depicts a simplified cross-sectional view of an electroplating apparatus. The apparatus includes an electroplating cell 1001, with substrate 1002 positioned in a substrate holder 1003. Substrate holder 1003 is often referred to as a cup, and it may support the substrate 1002 at its periphery. An anode 1004 is positioned near the bottom of the electroplating cell 1001. The anode 1004 is separated from the substrate 1002 by a membrane 1005, which is supported by a membrane frame 1006. Membrane frame 1006 is sometimes referred to as an anode chamber membrane frame, as it defines the top of the anode chamber housing the anode. Further, the anode 1004 is separated from the substrate 1002 by an ionically resistive element 1007. The ionically resistive element 1007 includes openings that allow electrolyte to travel through the ionically resistive element 1007 to impinge upon the substrate 1002. A front side insert 1008 is positioned above the ionically resistive element 1007, proximate the periphery of the substrate 1002. The front side insert 1008 may be ring-shaped and may be azimuthally non-uniform, as shown. The front side insert 1008 is sometimes also referred to as a cross flow confinement ring.

An anode chamber 1012 is below the membrane 1005, and is where the anode 1004 is located. An ionically resistive element manifold 1011 is above the membrane 1005 and below the ionically resistive element 1007. An inlet 1016, which may be connected with an irrigation flute 1040, delivers catholyte to the ionically resistive element manifold 1011 and may act to irrigate the membrane 1005 during electroplating. In this example, the inlet 1016 and irrigation flute 1040 are fed by electrolyte that passes through catholyte inlet 1018. A cross flow manifold 1010 is above the ionically resistive element 1007 and below the substrate 1002. The height of the cross flow manifold is considered to be the distance between the substrate 1002 and the plane of the ionically resistive element 1007 (excluding the ribs 1015 on the upper surface of the ionically resistive element 1007, if present). In some cases, the cross flow manifold may have a height between about 1 mm-4 mm, or between about 0.5 mm-15 mm. The cross flow manifold 1010 is defined on its sides by the front side insert 1008, which acts to contain the cross flowing electrolyte within the cross flow manifold 1010. A side inlet 1013 to the cross flow manifold 1010 is provided azimuthally opposite a side outlet 1014 to the cross flow manifold 1010. The side inlet 1013 and side outlet 1014 may be formed, at least partially, by the front side insert 1008.

As shown by the arrows in FIG. 10, electrolyte travels from the catholyte inlet 1018, through the side inlet 1013, into the cross flow manifold 1010, and out the side outlet 1014. In addition, electrolyte may travel through one or more inlets to the ionically resistive element manifold 1011 (e.g., inlets in irrigation flute 1040 and/or other inlets), into the ionically resistive element manifold 1011, through the openings in the ionically resistive element 1007, into the cross flow manifold 1010, and out the side outlet 1014. After passing through the side outlet 1014, the electrolyte spills over weir wall 1009. The electrolyte may be recovered and recycled.

In certain embodiments, the ionically resistive element 1007 approximates a nearly constant and uniform current source in the proximity of the substrate (cathode) and, as such, may be referred to as a high resistance virtual anode (HRVA) or channeled ionically resistive element (CIRP) in some contexts. Normally, the ionically resistive element 1007 is placed in close proximity with respect to the wafer. In contrast, an anode in the same close-proximity to the substrate would be significantly less apt to supply a nearly constant current to the wafer, but would merely support a constant potential plane at the anode metal surface, thereby allowing the current to be greatest where the net resistance from the anode plane to the terminus (e.g., to peripheral contact points on the wafer) is smaller. So while the ionically resistive element 1007 has been referred to as a high-resistance virtual anode (HRVA), this does not imply that electrochemically the two are interchangeable. Under certain operational conditions, the ionically resistive element 1007 would more closely approximate and perhaps be better described as a virtual uniform current source, with nearly constant current being sourced from across the upper plane of the ionically resistive element 1007.

The ionically resistive element 1007 contains micro size (typically less than 0.04″) through-holes that are spatially and ionically isolated from each other and do not form interconnecting channels within the body of ionically resistive element, in many but not all implementations. Such through-holes are often referred to as non-communicating through-holes. They typically extend in one dimension, often, but not necessarily, normal to the plated surface of the wafer (in some embodiments the non-communicating holes are at an angle with respect to the wafer which is generally parallel to the ionically resistive element front surface). Often the through-holes are parallel to one another. Often the holes are arranged in a square array. Other times the layout is in an offset spiral pattern. These through-holes are distinct from 3-D porous networks, where the channels extend in three dimensions and form interconnecting pore structures, because the through-holes restructure both ionic current flow and (in certain cases) fluid flow parallel to the surface therein, and straighten the path of both current and fluid flow towards the wafer surface. However, in certain embodiments, such a porous plate, having an interconnected network of pores, may be used as the ionically resistive element. When the distance from the plate's top surface to the wafer is small (e.g., a gap of about 1/10 the size of the wafer radius, for example less than about 5 mm), divergence of both current flow and fluid flow is locally restricted, imparted and aligned with the ionically resistive element channels.

One example of an ionically resistive element 1007 is a disc made of a solid, non-porous dielectric material that is ionically and electrically resistive. The material is also chemically stable in the plating solution of use. In certain cases the ionically resistive element 1007 is made of a ceramic material (e.g., aluminum oxide, stannic oxide, titanium oxide, or mixtures of metal oxides) or a plastic material (e.g., polyethylene, polypropylene, polyvinylidene difluoride (PVDF), polytetrafluoroethylene, polysulphone, polyvinyl chloride (PVC), polycarbonate, and the like), having between about 6,000-12,000 non-communicating through-holes. The ionically resistive element 1007, in many embodiments, is substantially coextensive with the wafer (e.g., the ionically resistive element 1007 has a diameter of about 300 mm when used with a 300 mm wafer) and resides in close proximity to the wafer, e.g., just below the wafer in a wafer-facing-down electroplating apparatus. Preferably, the plated surface of the wafer resides within about 10 mm, more preferably within about 5 mm of the closest ionically resistive element surface. To this end, the top surface of the ionically resistive element 1007 may be flat or substantially flat. Often, both the top and bottom surfaces of the ionically resistive element 1007 are flat or substantially flat. In a number of embodiments, however, the top surface of the ionically resistive element 1007 includes a series of linear ribs, as described further below.

As above, the overall ionic and flow resistance of the plate 1007 is dependent on the thickness of the plate and both the overall porosity (fraction of area available for flow through the plate) and the size/diameter of the holes. Plates of lower porosities will have higher impinging flow velocities and ionic resistances. Comparing plates of the same porosity, one having smaller diameter 1-D holes (and therefore a larger number of 1-D holes) will have a more micro-uniform distribution of current on the wafer because there are more individual current sources, which act more as point sources that can spread over the same gap, and will also have a higher total pressure drop (high viscous flow resistance).

In some cases, about 1-10% of the ionically resistive element 1007 is open area through which ionic current can pass (and through which electrolyte can pass if there is no other element blocking the openings). In particular embodiments, about 2-5% the ionically resistive element 1007 is open area. In a specific example, the open area of the ionically resistive element 1007 is about 3.2% and the effective total open cross sectional area is about 23 cm². In some embodiments, non-communicating holes formed in the ionically resistive element 1007 have a diameter of about 0.01 to 0.08 inches. In some cases, the holes have a diameter of about 0.02 to 0.03 inches, or between about 0.03-0.06 inches. In various embodiments the holes have a diameter that is at most about 0.2 times the gap distance between the ionically resistive element 1007 and the wafer. The holes are generally circular in cross section, but need not be. Further, to ease construction, all holes in the ionically resistive element 1007 may have the same diameter. However this need not be the case, and both the individual size and local density of holes may vary over the ionically resistive element surface as specific requirements may dictate.

The ionically resistive element 1007 shown in FIG. 10 includes a series of linear ribs 1015 that extend into/out of the page. The ribs 1015 are sometimes referred to as protuberances. The ribs 1015 are positioned on the top surface of the ionically resistive element 1007, and in many cases they are oriented such that their length (e.g., their longest dimension) is perpendicular to the direction of cross flowing electrolyte. In a particular embodiment, the ribs 1015 may be oriented such that their length is parallel to the direction of cross flowing electrolyte. The ribs 1015 affect the fluid flow and current distribution within the cross flow manifold 1010. For instance, the cross flow of electrolyte is largely confined to the area above the top surface of the ribs 1015, creating a high rate of electrolyte cross flow in this area. In the regions between adjacent ribs 1015, current delivered upward through the ionically resistive element 1007 is redistributed, becoming more uniform, before it is delivered to the substrate surface.

In FIG. 10, the direction of cross flowing electrolyte is left-to-right (e.g., from the side inlet 1013 to the side outlet 1014), and the ribs 1015 are oriented such that their lengths extend into/out of the page. In certain embodiments, the ribs 1015 may have a width (measured left-to-right in FIG. 10) between about 0.5 mm-1.5 mm, or between about 0.25 mm-10 mm. The ribs 1015 may have a height (measured up-down in FIG. 10) between about 1.5 mm-3.0 mm, or between about 0.25 mm-7.0 mm. The ribs 1015 may have a height to width aspect ratio (height/width) between about 5/1-2/1, or between about 7/1-1/7. The ribs 1015 may have a pitch between about 10 mm-30 mm, or between about 5 mm-150 mm. The ribs 1015 may have variable lengths (measured into/out of the page in FIG. 10) that extend across the face of the ionically resistive element 1007. The distance between the upper surface of the ribs 1015 and the surface of the substrate 1002 may be between about 1 mm-4 mm, or between about 0.5 mm-15 mm. The ribs 1015 may be provided over an area that is about coextensive with the substrate, as shown in FIG. 10. The channels/openings in the ionically resistive element 1007 may be positioned between adjacent ribs 1015, or they may extend through the ribs 1015 (in other words, the ribs 1015 may or may not be channeled). In some other embodiments, the ionically resistive element 1007 may have an upper surface that is flat (e.g., does not include the ribs 1015). The electroplating apparatus shown in FIG. 10, including the ionically resistive element with ribs thereon, is further discussed in U.S. Pat. No. 9,523,155, titled “ENHANCEMENT OF ELECTROLYTE HYDRODYNAMICS FOR EFFICIENT MASS TRANSFER DURING ELECTROPLATING,” which is herein incorporated by reference in its entirety.

The apparatus may include various additional elements as needed for a particular application. In some cases, an edge flow element may be provided proximate the periphery of the substrate, within the cross flow manifold. The edge flow element may be shaped and positioned to promote a high degree of electrolyte flow (e.g., cross flow) near the edges of the substrate. The edge flow element may be ring-shaped or arc-shaped in certain embodiments, and may be azimuthally uniform or non-uniform. Edge flow elements are further discussed in U.S. patent application Ser. No. 14/924,124, filed Oct. 27, 2015, titled “EDGE FLOW ELEMENT FOR ELECTROPLATING APPARATUS,” issued as U.S. Pat. No. 10,094,034, which is herein incorporated by reference in its entirety.

In some cases, the apparatus may include a sealing member for temporarily sealing the cross flow manifold. The sealing member may be ring-shaped or arc-shaped, and may be positioned proximate the edges of the cross flow manifold. A ring-shaped sealing member may seal the entire cross flow manifold, while an arc-shaped sealing member may seal a portion of the cross flow manifold (in some cases leaving the side outlet open). During electroplating, the sealing member may be repeatedly engaged and disengaged to seal and unseal the cross flow manifold. The sealing member may be engaged and disengaged by moving the substrate holder, ionically resistive element, front side insert, or other portion of the apparatus that engages with the sealing member. Sealing members and methods of modulating cross flow are further discussed in the following U.S. Patent Applications, each of which is herein incorporated by reference in its entirety: U.S. patent application Ser. No. 15/225,716, filed Aug. 1, 2016, titled “DYNAMIC MODULATION OF CROSS FLOW MANIFOLD DURING ELECTROPLATING”, and issued as U.S. Pat. No. 10,364,505; and U.S. patent application Ser. No. 15/161,081, filed May 20, 2016, titled “DYNAMIC MODULATION OF CROSS FLOW MANIFOLD DURING ELECTROPLATING”, and issued as U.S. Pat. No. 10,233,556.

In various embodiments, one or more electrolyte jet may be provided to deliver additional electrolyte above the ionically resistive element. The electrolyte jet may deliver electrolyte proximate a periphery of the substrate, or at a location that is closer to the center of the substrate, or both. The electrolyte jet may be oriented in any position, and may deliver cross flowing electrolyte, impinging electrolyte, or a combination thereof. Electrolyte jets are further described in U.S. patent application Ser. No. 15/455,011, filed Mar. 9, 2017, titled “ELECTROPLATING APPARATUS AND METHODS UTILIZING INDEPENDENT CONTROL OF IMPINGING ELECTROLYTE,” and published as U.S. Patent Application Publication No. 2018/0258546, which is herein incorporated by reference in its entirety.

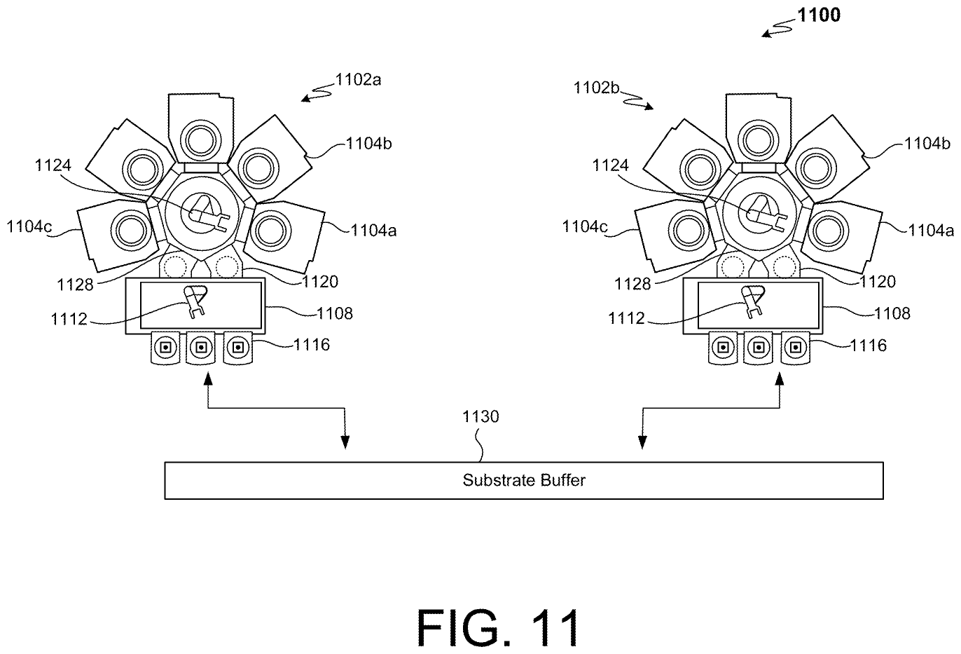

The SRP removal processes described may be implemented in a chamber, which may be part of a substrate processing system. The substrate processing system may further include one or more additional substrate processing tools used to process substrates including deposition of SRPs and upstream and downstream processing. Referring now to FIG. 11, a substrate processing system 1100 includes one or more substrate processing tools 1102 (substrate processing tools 1102a and 1102b are shown for illustration purposes) and substrate buffer 1130 or other substrate storage. Each of the substrate processing tools 1102a and 1102b includes a plurality of processing chambers 1104a, 1104b, 1104c, etc. (collectively processing chambers 1104). For example only, each of the processing chambers 1104 may be configured to perform a substrate treatment. In some examples, the substrates may be loaded into one of the processing chambers 1104, processed, and then moved to one or more other ones of the processing chambers 1104 and/or removed from the substrate processing tool 1100 (e.g., if all perform the same treatment).

Substrates to be processed are loaded into the substrate processing tools 1102a and 1102b via ports of a loading station of an atmosphere-to-vacuum (ATV) transfer module 1108. In some examples, the ATV transfer module 1108 includes an equipment front end module (EFEM). The substrates are then transferred into one or more of the processing chambers 1104. For example, a transfer robot 1112 is arranged to transfer substrates from loading stations 1116 to load locks 1120. A vacuum transfer robot 1124 of a vacuum transfer module 1128 is arranged to transfer substrates from the load locks 1120 to the various processing chambers 1104.

After processing in one or more of the substrate processing tools 1102a and 1102b, the substrates may be transported outside of a vacuum environment. For example, the substrates may be moved to a location for storage (such as the substrate buffer 1130). In other examples, the substrates may be moved directly from the substrate processing tool to another substrate processing tool for further processing or from the storage buffer 1130 to another substrate processing tool for further processing.

Exposure of the metal feature(s) or substrate to ambient conditions may cause defects or otherwise adversely impact downstream processing. A sacrificial capping layer including an SRP can be added to the metal feature(s) or substrate prior to exposure to ambient conditions. In some examples, the sacrificial capping layer is applied in the substrate processing tool prior to transferring the substrate to the substrate buffer for storage or to another substrate processing tool, such as for thermocompressive bonding. In other examples, the sacrificial capping layer is applied in another processing chamber (not associated with the substrate processing tool).

Prior to performing another treatment on the substrate (e.g., prior to bonding the metal features), the sacrificial capping layer is removed as described herein. For example, the substrate may be transferred to the substrate processing tool 1102b after a period of storage in the storage buffer 1130 or after processing in the substrate processing tool 1102a. The sacrificial capping layer may be removed in one of the processing chambers in the substrate processing tool 1102b, or another processing chamber (not associated with the substrate processing tool 1102b). In some embodiments, the sacrificial capping layer is removed in a load lock 1120.

In some examples, the sacrificial capping layer is applied by a processing chamber in the same substrate processing tool (that performed electroplating or substrate treatment) prior to exposure to ambient conditions. Since the substrate processing tool operates at vacuum, exposure of the substrate to ambient conditions is prevented. In some examples, the sacrificial layer is deposited after a wet clean process or a plasma treatment process. In this case, oxides and residues may be removed by the wet clean process or the plasma treatment process, and the sacrificial capping layer is deposited in sequence prior to drying the wafer or immediately after drying the wafer. In some examples, this process is not done under vacuum and is done without any exposure of the dry pristine surface to the ambient. In other examples, the substrate is transported from the substrate processing tool to another processing chamber located outside of the substrate processing tool that adds the sacrificial capping layer. Using this approach limits or reduces the period of exposure of the substrate to ambient conditions. Exposure is limited to a brief period of transport from the substrate processing tool to the processing chamber where the sacrificial capping layer is applied. Storage of the substrate may be performed for longer periods without additional exposure to ambient conditions.

Subsequently, the sacrificial capping layer may be removed prior to further processing. In some examples, the sacrificial capping layer is removed in another substrate processing tool under vacuum conditions prior to substrate treatment in processing chambers of the same substrate processing tool. In other examples, the substrate is transported to a processing chamber that removes the sacrificial capping layer and then to the substrate processing tool for further processing. This approach also limits exposure to ambient conditions between the processing chamber and the substrate processing tool or other environment. In one example, the sacrificial capping layer is formed immediately after etch, deposition, or other process by exposing the substrate to a small molecule vapor that condenses on the surface to form a film. This can be performed directly inside the tool in which the etch or deposition occurred (e.g., substrate processing tool 1102a) and may occur in the same processing chamber in which the etch or deposition occurred. The substrate is then taken to the next tool for processing (e.g., substrate processing tool 1102b). Once the substrate is again no longer exposed to ambient conditions (for example by bringing the substrate under vacuum or an atmosphere purged with an inert gas), vacuum and compounds, and in some cases, other stimuli, as described above are applied to induce the film to degrade and be removed from the substrate. This may take place inside of a processing chamber as described above (e.g., process chamber 1104a of substrate processing chamber 1102b).

The metal-metal bonding processes described herein may be implemented in a bonding chamber, which may be part of a substrate processing system. Alternatively, the metal-metal bonding tool can be located in proximity to the processing chamber for SRP removal, in which transfer passages, transfer chambers, and/or handling robots coordinate movement of the wafer from the SRP removal chamber to the bonding tool. The bonding tool or chamber can be configured to provide the bonding temperature or bonding pressure described herein. Non-limiting bonding tools and chambers include thermocompressive bonding tools or other bonding platforms, such as the EVG®500 Series bonding module from EV Group (EV Group Europe & Asia/Pacific GmbH, Sankt Florian am Inn, Austria), XBS200 platform or SB6/8 Gen2 platform from SÜSS MicroTec SE (Garching, Germany), Esec series for die bonding and Datacon series (e.g., Datacon 8800 TC) for die attaching from BE Semiconductor Industries N.V. (Duiven, Netherlands), and Fineplacer series for bonding from Finetech GmbH & Co. KG (Berlin, Germany).

In various embodiments, a system controller is employed to control process conditions during processing including during the SRP removal and/or metal bond formation. The controller will typically include one or more memory devices and one or more processors. A processor may include a CPU or computer, analog and/or digital input/output connections, stepper motor controller boards, etc.

The controller may control all the activities of a removal apparatus. The system controller executes system control software, including sets of instructions for controlling the timing, mixture of gases, chamber pressure, chamber temperature, wafer temperature, wafer chuck or pedestal position, plasma power, and other parameters of a particular process. Other computer programs stored on memory devices associated with the controller may be employed in some embodiments.

Typically, there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the reactant pulses and purge gas flows and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, substrate temperature, and plasma power. These parameters are provided to the user in the form of a recipe and may be entered utilizing the user interface.

Signals for monitoring the process may be provided by analog and/or digital input connections of the system controller. The signals for controlling the process are output on the analog and digital output connections of the system.

The system software may be designed or configured in many ways.

For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

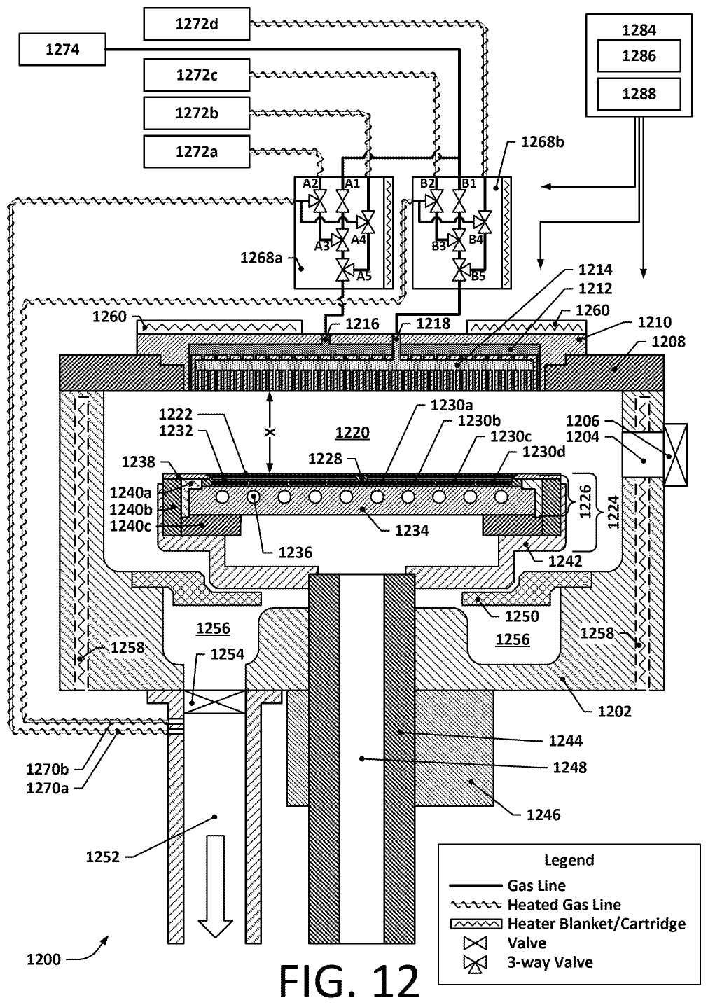

FIG. 12 shows an example of a deposition chamber (e.g., for vapor-based deposition, such as for an SRP). As can be seen, an apparatus 1200 is depicted that has a processing chamber 1202 that includes a lid 1208. The processing chamber 1202 may include a wafer transfer passage 1204 through one of the walls of the processing chamber 1202 that is sized to allow a substrate 1222 to be passed therethrough and into the interior of the processing chamber 1202, where the substrate 1222 may be placed on a wafer support 1224. The wafer transfer passage 1204 may have a gate valve 1206 or similar door mechanism that may be operated to seal or unseal the wafer transfer passage, thereby allowing the environment within the processing chamber 1202 to be isolated from the environment on the other side of the gate valve 1206. For example, the processing chamber 1202 may be provided substrates 1222 via a wafer handling robot that is located in an adjoining transfer chamber. Such a transfer chamber may, for example, have multiple processing chambers 1202 arranged around its periphery, with each such processing chamber 1202 connected with the transfer chamber via a corresponding gate valve 1206.

The wafer support 1224 may, for example, include an electrostatic chuck (ESC) 1226, which may be used to provide a wafer support surface for supporting the substrate 1222. The ESC 1226 may include, for example, a base plate 1234 that is bonded to a top plate 1228 that is placed atop the base plate 1234. The top plate 1228 may, for example, be made of a ceramic material and may have embedded within it several other components. In the depicted example, the top plate 1228 has two separate electrical systems embedded within it. One such system is an electrostatic clamping electrode system, which may have one or more clamping electrodes 1232 that may be used to generate an electric charge within the substrate 1222 that causes the substrate 1222 to be drawn against the wafer support surface of the top plate 1228. In the implementation of FIG. 12, there are two clamping electrodes 1232 that provide a bi-polar electrostatic clamping system, although some implementations may use only a single clamping electrode 1232 to provide a mono-polar electrostatic clamping system.

The other system is a thermal control system that may be used to control the temperature of the substrate 1222 during processing conditions. In FIG. 12, the thermal control system is a multi-zone thermal control system featuring four annular resistance heater traces 1230a, 1230b, 1230c, and 1230d that are concentric with one another and positioned beneath the clamping electrodes 1232. The center resistance heater traces 1230a may, in some implementations, fill a generally circular area, and each resistance heater trace 1230a/b/c/d may follow a generally serpentine or otherwise meandering path within a corresponding annular region. Each resistance heater trace 1230a/b/c/d may be individually controlled to provide a variety of radial heating profiles in the top plate 1228; such a four-zone heating system may, for example, be controlled to maintain the substrate 1222 so as to have a temperature uniformity of ±0.5° C. in some cases. While the apparatus 1200 of FIG. 12 features a four-zone heating system in the ESC 1226, other implementations may use single-zone or multi-zone heating systems having more or fewer than four zones.

In some implementations, of, for example, temperature control mechanisms discussed above, heat pumps may be used instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the top plate 1228 (and thus the substrate 1222) and direct it into the baseplate 1234 and the heat exchange passages 1236, thereby allowing the substrate 1222 to be cooled more rapidly and more effectively, if desired.

The ESC 1226 may also include, for example, a base plate 1234 that may be used to provide structural support to the underside of the top plate 1228 and which may also act as a heat dispersion system. For example, the base plate 1234 may include one or more heat exchange passages 1236 that are arranged in a generally distributed fashion throughout the base plate 1234, e.g., the heat exchange passages 1236 may follow a serpentine, circular switchback, or spiral pattern around the center of the base plate 1234. A heat exchange medium, e.g., water or inert fluorinated liquid, may be circulated through the heat exchange passages 1236 during use. The flow rate and temperature of the heat exchange medium may be externally controlled so as to result in a particular heating or cooling behavior in the base plate 1234.

The ESC 1226 may, for example, be supported by a wafer support housing 1242 that is connected with, and supported by, a wafer support column 1244. The wafer support column 1244 may, for example, have a routing passage 1248 other pass-throughs for routing cabling, fluid flow conduits, and other equipment to the underside of the base plate 1234 and/or the top plate 1228. For example, while not shown in FIG. 12, cabling for providing electrical power to the resistance heater traces 1230a/b/c/d may be routed through the routing passage 1248, as may cabling for providing electrical power to the clamping electrodes 1232. Other cables, e.g., cables for temperature sensors, may also be routed through the routing passage 1248 to locations in the interior of the wafer support 1224. In implementations with a temperature-controllable base plate 1234, conduits for conveying heat exchange medium to and from the base plate 1234 may also be routed through the routing passage 1248. To avoid undue clutter, such cables and conduits are not depicted in FIG. 12, but it is to be understood that they would, nonetheless, be present.

The apparatus 1200 of FIG. 12 also includes a wafer support z-actuator 1246 that may provide movable support to the wafer support column 1244. The wafer support z-actuator 1246 may be actuated to cause the wafer support column 1244, and the wafer support 1224 supported thereby, to move up or down vertically, e.g., by up to several inches, within a reaction space 1220 of the processing chamber 1202. In doing so, a gap distance X between the substrate 1222 and the underside of the showerhead 1210 may be tuned depending on various process conditions.

The wafer support 1224 may also include, in some implementations, one or more edge rings that may be used to control and/or fine-tune various process conditions. In FIG. 12, an upper edge ring 1238 is provided that lies on top of, for example, lower edge rings 1240a and 1240b, which, in turn, are supported by the wafer support housing 1242 and a third lower edge ring 1240c. The upper edge ring 1238 may, for example, be generally subjected to the same processing environment as the substrate 1222, whereas the lower edge rings 1240a/b/c may generally be shielded from the processing environment. Due to the increased exposure of the upper edge ring 1238, the upper edge ring 1238 may have a limited lifespan and may require more frequent replacement or cleaning as compared with the lower edge rings 1240a/b/c.

The apparatus 1200 may also include a system for removing process gases from the processing chamber 1202 during and after processing concludes. For example, the processing chamber 1202 may include an annular plenum 1256 that encircles the wafer support column 1244. The annular plenum 1256 may, in turn, be fluidically connected with a vacuum foreline 1252 that may be connected with a vacuum pump, e.g., such as may be located beneath a subfloor below the apparatus 1200. A regulator valve 1254 may be provided in between the vacuum foreline 1252 and the processing chamber 1202 and actuated to control the flow into the vacuum foreline 1252. In some implementations, a baffle 1250, e.g., an annular plate or other structure that may serve to make the flow into the annular plenum 1256 more evenly distributed about the circumference of the wafer support column 1244, may be provided to reduce the chances of flow non-uniformities developing in reactants flowed across the substrate 1222.

The showerhead 1210, as shown, is a dual-plenum showerhead 1210 and includes a first plenum 1212 that is provided process gas via a first inlet 1216 and a second plenum 1214 that is provided process gas via a second inlet 1218. The showerhead 1210 may, in some implementations, have one plenum or more than two plenums. In some instances, a single plenum is used to deliver the SRP into the reaction space 1220 of the processing chamber 1202. Each plenum may have a corresponding set of gas distribution ports that fluidically connect the respective plenum with the reaction space 1220 through the faceplate of the showerhead 1210 (the faceplate being the portion of the showerhead 1210 that is interposed between the lowermost plenum and the reaction space 1220).

The first inlet 1216 and the second inlet 1218 of the showerhead 1210 may be provided processing gases via a gas supply system, which may be configured to provide one or more SRPs, as discussed herein.

A first valve manifold 1268a may be configured to provide an SRP to the first inlet 1216, while a second valve manifold 1268b may be configured to provide another SRP or other reactant to the second inlet 1218. In this example, the first valve manifold 1268a, for example, includes multiple valves A1-A5. Valve A2 may, for example, be a three-way valve that has one port fluidically connected with a first vaporizer 1272a, another port fluidically connected with a bypass line 1270a, and a third port fluidically connected with a port on another 3-way valve A3. Similarly, valve A4 may be another three-way valve that has one port fluidically connected with a second vaporizer 1272b, another port fluidically connected with the bypass line 1270a, and a third port fluidically connected with a port on another 3-way valve A5. One of the other ports on valve A5 may be fluidically connected with the first inlet 1216 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 1274, e.g., nitrogen, argon, or other suitably inert gas (with respect to SRP). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 1268a may, for example, be controllable to cause vapors from one or both of the vaporizers 1272a and 1272b to be flowed either to the processing chamber 1202 or through the first bypass line 1270a and into the vacuum foreline 1252. The first valve manifold 1268a may also be controllable to cause a purge gas to be flowed from the purge gas source 1274 and into the first inlet 1216.

For example, to flow vapor from the first vaporizer 1272a into the reaction space 1220, the valve A2 may be actuated to cause the vapor from the first vaporizer 1272a to first flow into the first bypass line 1270a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 1272a to be directed to the first inlet. Similar operations with valves A4 and A5 may be performed to deliver vapor from the second vaporizer 1272b to the first inlet 1216. In some instances, it may be desirable to purge one of the vapors from the first plenum 1212 by actuating the valves A1, A3, and A5 so as to cause the purge gas from the purge gas source 1274 to be flowed into the first inlet 1216. In some additional implementations, it may be desirable to simultaneously flow vapor from one of the vaporizers 1272a or 1272b in tandem with flowing gas from the purge gas into the first inlet 1216. Such implementations may be used to dilute the concentration of the reactant(s) contained in such vapor(s).

It will be appreciated that the second valve manifold 1268b may be controlled in a similar manner, e.g., by controlling valves B1-B5, to provide vapors from vaporizers 1272c and 1272d to the second inlet 1218 or to the second bypass line 1270b. It will be further appreciated that different manifold arrangements may be utilized as well, including a single unitary manifold that includes valves for controlling flow of the SRPs or other reactants to the first inlet 1216 and the second inlet 1218.

As mentioned earlier, some apparatuses 1200 may feature a lesser number of vapor sources, e.g., only two vaporizers 1272, in which case the valve manifold(s) 1268 may be modified to have a lesser number of valves, e.g., only valves A1-A3.

As discussed above, apparatuses such as apparatus 1200, which may be used to provide for dry deposition of SRP films, may be configured to maintain particular temperature profiles within the processing chamber 1202. In particular, such apparatuses 1200 may be configured to maintain the substrate 1222 at a lower temperature, e.g., at least 25° C. to 50° C. lower, than most of the equipment of the apparatus 1202 that comes into direct contact with the SRP(s). Additionally, the temperature of the equipment of the apparatus 1200 that comes into direct contact with the SRP(s) may be kept to an elevated level that is sufficiently high that condensation of the vaporized reactants on the surfaces of such equipment is discouraged. At the same time, the substrate 1222 temperature may be controlled to a level that promotes condensation, or at least deposition, of the reactants on the substrate 1222.

To provide for such temperature control, various heating systems may be included in the apparatus 1200. For example, the processing chamber 1202 may have receptacles for receiving cartridge heaters 1258, e.g., for a processing chamber 1202 that has a generally cylindrical interior volume but a square or rectangular external shape, vertical holes for receiving cartridge heaters 1258 may be bored into the four corners of the chamber 1202 housing. In some implementations, the showerhead 1210 may be covered with heater blankets 1260, which may be used to apply heat across the exposed upper surface of the showerhead 1210 to keep the showerhead temperature elevated. It may also be beneficial to heat various gas lines that are used to conduct the vaporized reactants from the vaporizers 1272 to the showerhead 1210. For example, resistive heater tape may be wound around such gas lines and used to heat them to an elevated temperature. As shown in FIG. 12, all of the gas lines that potentially have SRP(s) flowing through them are shown as being heated, including the bypass lines 1270. The only exceptions are the gas lines from the valve manifolds 1268 to the first inlet 1216 and the second inlet 1218, which may be quite short and may be indirectly heated by the showerhead 1210. Of course, even these gas lines may be actively heated, if desired. In some implementations, heaters may be provided proximate to the gate valve 1206 to provide heat to the gate valve as well.

The various operational systems of the apparatus 1200 may be controlled by a controller 1284, which may include one or more processors 1286 and one or more memory devices 1288 that are operatively connected with each other and that are communicatively connected with various systems and subsystems of the apparatus 1200 so as to provide for control functionality for those systems. For example, the controller 1284 may be configured to control the valves A1-A5 and B1-B5, the various heaters 1258, 1260, the vaporizers 1272, the regulator valve 1254, the gate valve 1206, the wafer support z-actuator, and so forth.

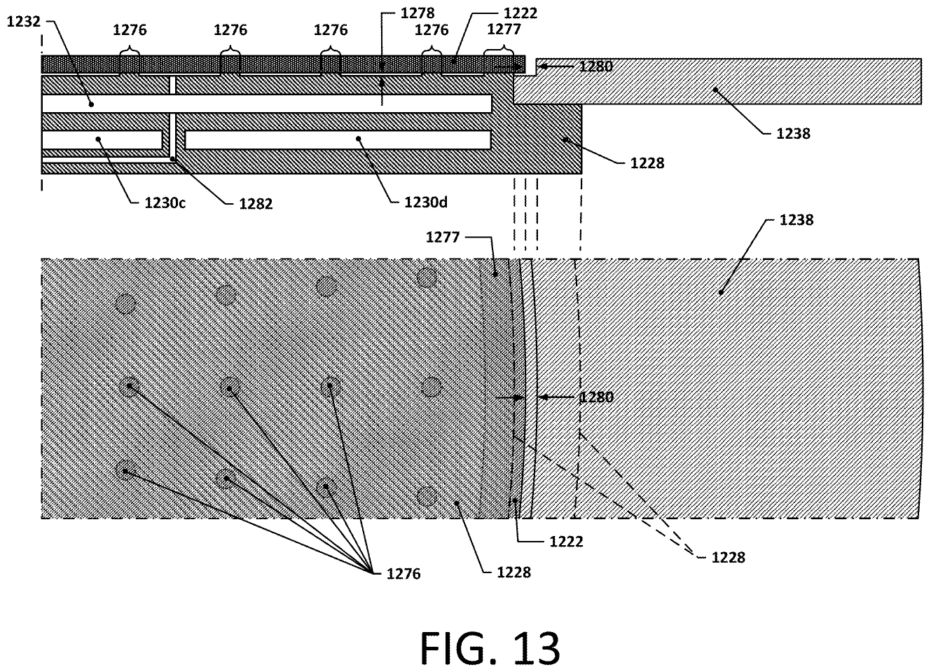

Another feature that the apparatus 1200 may include is shown in FIG. 13, which depicts close-up side cross-sectional and plan views of a portion of the substrate 1222, top plate 1228, and upper edge ring 1238 of FIG. 12. As can be seen, in some implementations, the substrate 1222 may be elevated off of most of the top plate 1228 by a plurality of small mesas 1276, which may be shallow bosses that protrude from the nominal upper surface of the top plate 1228 by a small distance so as to provide for a backside gap 1278 between the underside of the substrate 1222 and the majority of the top plate 1228. A circumferential wall feature 1277 may be provided at the periphery of the top plate 1228. The circumferential wall feature 1277 may extend around the entire perimeter of the top plate 1228 and be of nominally the same height as the mesas 1276. During processing operations, a generally inert gas, such as helium, may be flowed into the backside gap 1278 via one or more gas ports 1282. This gas may then flow radially outward before encountering the circumferential wall feature 1277, which way then restrict such radially outward flow and cause a higher-pressure region of the gas to be trapped between the substrate 1222 and the top plate 1228. The inert gas that leaks past the circumferential wall 1277 may eventually flow out through a radial gap 1280 between the outer edge of the substrate 1222 and a portion of the upper edge ring 1238. Such gas may serve to protect the underside of the substrate from undesirably being affected by the processing operations being performed by acting to prevent the gases released by the showerhead 1210 from reaching the underside of the substrate 1222. At the same time, the gas released into the backside gap 1278 region may also act to increase thermal coupling between the substrate 1222 and the top plate 1228, thereby allowing the top plate 1228 to more effectively heat or cool the substrate 1222. Due to the higher pressure provided by the circumferential wall, the gas that is within the backside gap 1278 region may also be at a higher density than gas in the remainder of the chamber, and may thus provide more effective thermal coupling between the substrate 1222 and the top plate 1228.

The controller 1284 may be configured, e.g., via execution of computer-executable instructions, to cause the apparatus 100 to perform various operations consistent with the disclosure provided above.

Once the SRP layer has been deposited on the substrate 1222, the substrate 1222 may, as noted above, be transferred to one or more subsequent processing chambers or tool for additional operations (e.g., any described herein). Further deposition apparatuses are described in International Patent Application No. PCT/US2020/038968, filed Jun. 22, 2020, titled “APPARATUS FOR PHOTORESIST DRY DEPOSITION,” which is herein incorporated by reference in its entirety.

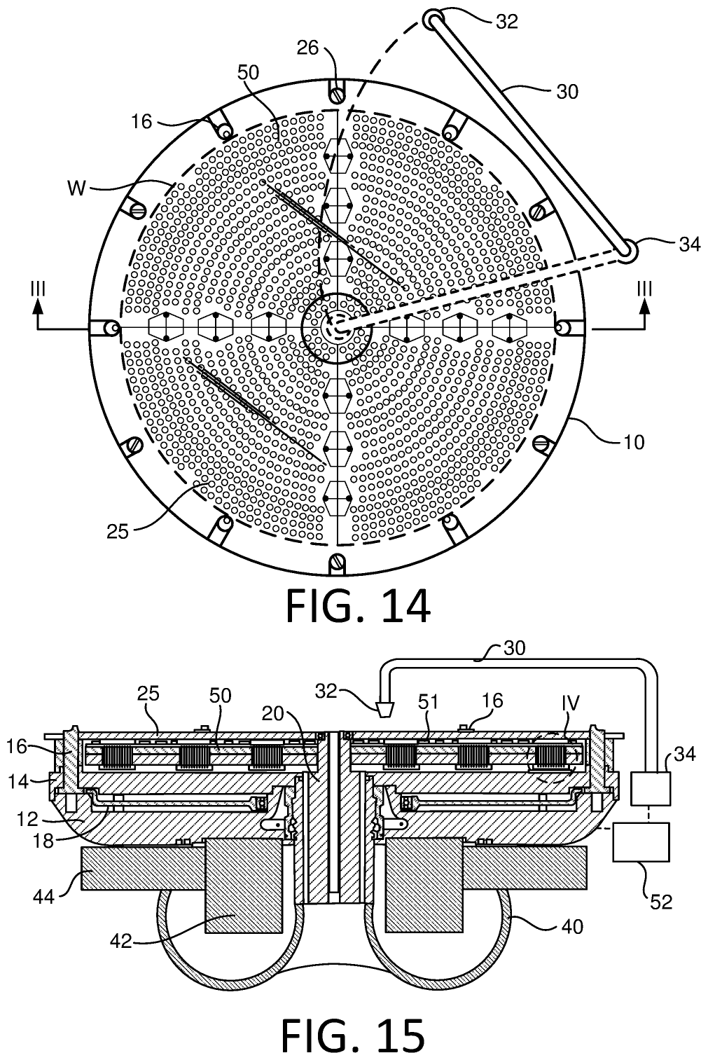

Solvent- or liquid-based deposition can employ an apparatus having a liquid dispensing system and a heater. FIG. 14 shows an example of an apparatus, in which a rotary chuck 10 is designed to hold and rotate a wafer W of a predetermined diameter, for example 300 mm or 450 mm. Wafer W is held by a circular series of gripping pins 16, which in this embodiment are six in number. Pins 16 pass through openings in a transparent plate 25 made of quartz or sapphire. Plate 25 is secured to chuck 10 by screws 26 and rotates with the chuck 10. When a wafer W is positioned on the chuck, it is held above the plate 25 so that the lower surface of the wafer is parallel to the plate 25 and spaced therefrom by a small gap.

Beneath the transparent plate 25 is mounted a radiant heating assembly 50, which will be described in greater detail below.

Adjacent the chuck 10, a boom swing arm 30 is mounted for pivotal motion about its drive motor 34. Arm 30 is supplied with process and/or rinse liquid, which is discharged downwardly through its discharge nozzle 32. Boom swing arm 30 is movable between a standby position shown in solid line in FIG. 14, and a central position shown in broken line. Discharge nozzle 32 can therefore scan across the full radius of a wafer W, and when a wafer W is rotated by chuck 10, thereby dispense liquid onto its entire upwardly-facing surface.

Turning now to FIG. 15, it can be seen that the rotary chuck 10 is made up of a lower chuck body 12 and an upper chuck body 14, which are secured to one another and are journalled for rotation about a stationary central post 20. The pins 16 and transparent plate 25 also rotate with the chuck 10 in this embodiment, as does the ring gear 18 which is in continuous meshing engagement with each of the gripping pins 16 via gear teeth provided at the bases of these latter. Ring gear 18 can also rotate relative to the chuck 10 to a limit extent, thereby to rotate pins 16 about their respective axes and move the uppermost eccentric gripping portions between their open and closed positions, in a manner well known per se.

The stationary post 20 is mounted on a machine frame 40 of the apparatus, as is a stator 44, whereas rotor 42 is secured to the lower chuck body 12, with the stator 44 and rotor 42 constituting a magnetic motor that drives the chuck 10 in rotation. Further particulars of the overall chuck structure are described for example in commonly-owned U.S. Pat. No. 9,245,777.

Radiant heating assembly 50 in this embodiment is mounted on the stationary post 20, and therefore does not rotate, whereas it is enveloped by the rotating structure of the chuck comprising elements 25, 14, 16. Radiant heating assembly 50 in this embodiment comprises a multiplicity of blue light emitting diodes (LEDs) 51 mounted facing the transparent plate 25, and a controller 52 (e.g. an on-board controller (not shown) mounted on the underside of heating assembly 50). Controller 52 controls the turning on and off, as well as the power, of the blue LEDs 51, and also communicates wirelessly with the motor 34 of the boom swing arm 30.

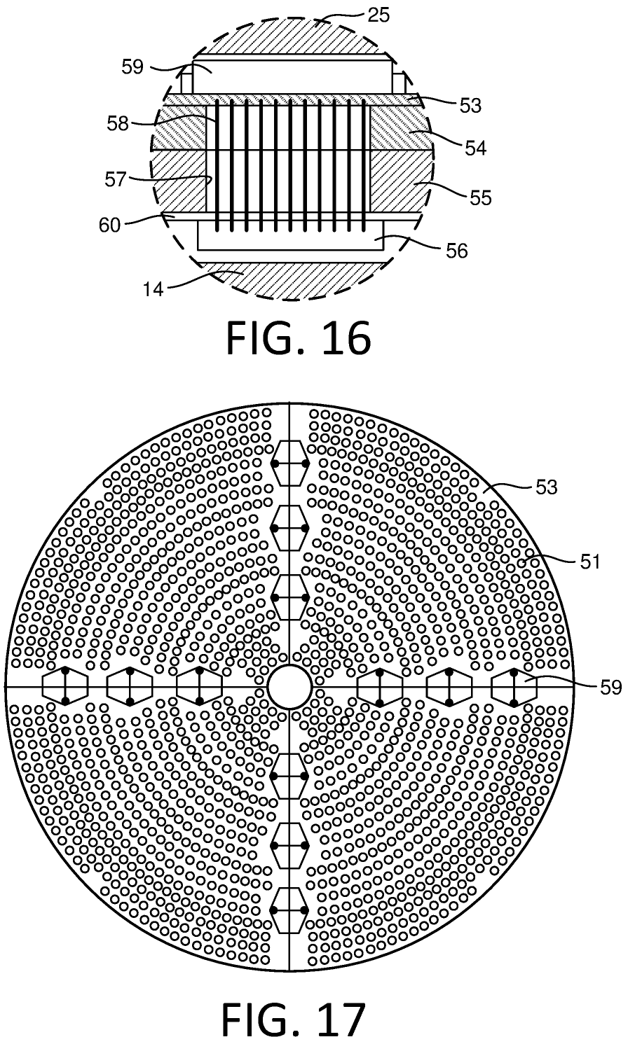

As shown in FIG. 16, the radiant heating assembly 50 is composed of an aluminum substrate made up of upper and lower pieces 54 and 55 that are brazed together, the aluminum substrate serving as a heat sink to prevent excessive heating of the structure beneath the blue LED elements 51. A printed circuit board (PCB) 53 is mounted on top of upper piece 54, on which the traces for the LED elements are formed and on which the LED elements 51 are mounted.

Onboard chips 56 are mounted on a printed circuit board 60 secured to the underside of lower piece 55. Wires 58 interconnecting the output pins of onboard chips 56 and the input terminals of the traces formed on PCB 53 are accommodated in pockets 57 that pass through the aluminum substrate 53, 54.

As shown in FIG. 17, the PCB 53 of this embodiment is formed in four quadrants, which are joined together by connectors 59. The LED elements 51 are formed in groups of sixteen, i.e., the arrangement of onboard chips 56 and the connections from those chips to PCB 53, along with the onboard controller 52, permit the LEDs to be powered individually in groups as small as sixteen.

It will be seen in FIG. 17 that the LEDs 51 are arranged in twenty concentric circles, and that the number of LEDs in each circle is a multiple of sixteen. Thus, each concentric circle can be individually controlled as a separate heating zone, by virtue of the arrangement described above.

The blue LED lamps 51 have a maximum intensity at a wavelength of about 450 nm. Other sources of radiation could be used, but it is preferred to use sources emitting radiation having a maximum intensity in a wavelength range from 390 nm to 550 nm and more preferably in a wavelength range from 400 nm to 500 nm.

Whereas radiation of that wavelength characteristic is largely transmitted by the plate 25, that same radiation is largely absorbed by the semiconductor material of the wafer W, especially when the wafer W is silicon.

This arrangement allows very fast local heating of the wafer W, in a manner that causes evaporation of rinse liquid before the damaging meniscus has a chance to form. For example, each LED 51 may have a power consumption of 10 W and provides a light power of 3 W, which light power can be generated nearly instantaneously. Additionally, lesser light powers can be generated for selected LEDs 51 when desired, for examples by pulsing the power supply to selected LEDs 51 at for example 500 Hz, in a manner known per se.

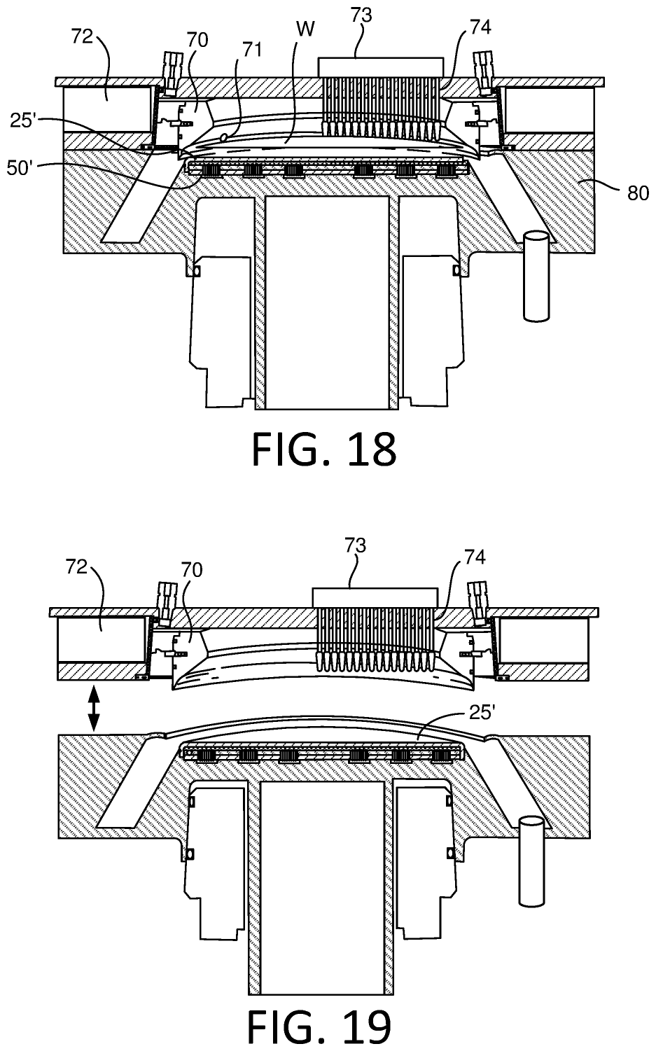

FIGS. 18-19 show an alternative embodiment in which the chuck is a magnetic ring rotor 70 positioned within a closed chamber 80, and driven in rotation by a stator 72 positioned outside of the chamber 80. A wafer W is held by gripping elements 71 that project downwardly from the ring rotor 70.

The chamber 80 can be opened for loading and removal of a wafer W as shown in FIG. 19. The heating assembly 50′ is incorporated into the lower part of housing 80, and is generally similar to that described in connection with the preceding embodiment, except that in this embodiment the transparent plate 25′ is stationary and does not rotate with the magnetic rotor 70.

Furthermore, in this embodiment, instead of a radially movable liquid dispenser 30, there is provided a series of fixed liquid dispensing nozzles 74 fed by a manifold 73. Rinse liquid can be supplied serially to these nozzles 74, starting with the most central and continuing to the most peripheral, so as to approximate the dispensing action of the boom swing arm 30 of the preceding embodiments. In this case, therefore, the controller 52 would control the power supply to the selected groups of LEDs 51 based on which nozzle 74 was dispensing liquid. Further apparatuses and components are described in U.S. Pat. No. 10,720,343, issued to Mui et al., titled “METHOD AND APPARATUS FOR PROCESSING WAFER-SHAPED ARTICLES,” which is herein incorporated by reference in its entirety.

In some implementations, a controller is part of a system, which may be part of any of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck. A plasma power program may control plasma power.

Examples of chamber sensors that may be monitored during removal include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an R_{F} or microwave plasma resist stripper.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
aligning a first capped feature with a second capped feature, wherein each of the first and second capped features comprises, independently, a stimulus responsive polymer (SRP) layer disposed on a surface of a metal feature; and
bonding the first and second capped features in an environment that removes the SRP and forms a metal-metal bond between the metal features.

2. The method of claim 1, wherein the SRP layer prevents oxidation of the metal feature.

3. The method of claim 1, wherein said bonding comprises:
exposing the first and second capped features to a removal temperature that removes the SRP, thereby providing exposed metal features; and
contacting the exposed metal features to form the metal-metal bond.

4. The method of claim 3, wherein said exposing includes use of an acidic vapor, heat, an extreme ultraviolet or ultraviolet or vacuum ultraviolet light, a plasma, metastable neutrals from a noble gas plasma, or combinations thereof.

5. The method of claim 1, wherein said bonding includes use of an inert atmosphere, a vacuum environment, a reducing gas, or ambient air.

6. The method of claim 1, wherein the metal feature comprises copper (Cu), tin (Sn), silver (Ag), gold (Au), aluminum (Al), or alloys thereof.

7. The method of claim 1, further comprising, prior to said aligning:
(i) depositing a first SRP layer on a surface of a first metal feature, thereby providing the first capped feature; and
(ii) depositing a second SRP layer on a surface of a second metal feature, thereby providing the second capped feature.

8. The method of claim 7, wherein the first SRP layer is further disposed on a surface of a gap fill layer surrounding the first metal feature.

9. The method of claim 8, wherein the second SRP layer is further disposed on a surface of a gap fill layer surrounding the second metal feature.

10. The method of claim 7, further comprising, prior to said depositing in at least one of (i) and (ii):
pretreating a surface of the first and second metal features to perform at least one of cleaning the surface and removing an oxide layer.

11. The method of claim 7, wherein said depositing in (i) and/or (ii) comprises vapor-based or solvent-based deposition of the SRP.

12. A method comprising:
depositing a stimulus responsive polymer (SRP) to form an SRP layer on a surface of a first metal feature comprising an electrical contact, thereby providing a first capped feature.

13. The method of claim 12, further comprising, after said depositing:
removing the SRP layer to provide a first exposed metal feature; and
contacting the first exposed metal feature to a second exposed metal feature, thereby forming a metal-metal bond between the exposed metal features.

14. The method of claim 12, wherein said depositing comprises vapor-based or solvent-based deposition of the SRP.

15. The method of claim 12, wherein said removing comprises exposing the SRP layer to heat, an extreme ultraviolet or ultraviolet or vacuum ultraviolet light, metastable neutrals from a noble gas plasma, an acidic vapor, or a basic vapor.

16. The method of claim 12, wherein the SRP layer prevents oxidation of the first metal feature.

17. The method of claim 12, wherein the SRP layer has a thickness of about 10 nm to 10 μm.

18. The method of claim 13, further comprising:
depositing an SRP to form an SRP layer on a surface of the second metal feature, thereby providing a second capped feature; and
removing the SRP layer from the second capped feature to provide the second exposed metal feature.

19. The method of claim 18, further comprising:
removing the SRP layer from the second capped feature to provide an exposed metal feature; and
bonding the exposed first and second metal features, thereby forming a metal-metal bond.

20. The method of claim 12, wherein the electrical contact comprises a raised metal pillar, a bond pad, a bump, a microbump, a metal contact surrounded by a dielectric, or an interconnect.

21. A method comprising:
depositing a stimulus responsive polymer (SRP) to form an SRP layer on a surface of a first metal feature and a second metal feature, thereby providing a first capped feature and a second capped feature;
aligning the first capped feature with the second capped feature;
removing the SRP layer to provide exposed metal features; and
contacting the exposed metal features, thereby forming a metal-metal bond between the exposed metal features.

22. The method of claim 21, wherein the SRP further comprises an acid catalyst, an organic acid, a photoacid generator, or a thermal acid generator.

23. The method of claim 1, wherein the SRP further comprises a metal-binding moiety.

24. The method of claim 1, wherein the SRP comprises a structure of one of formulas (I)-(XIII): 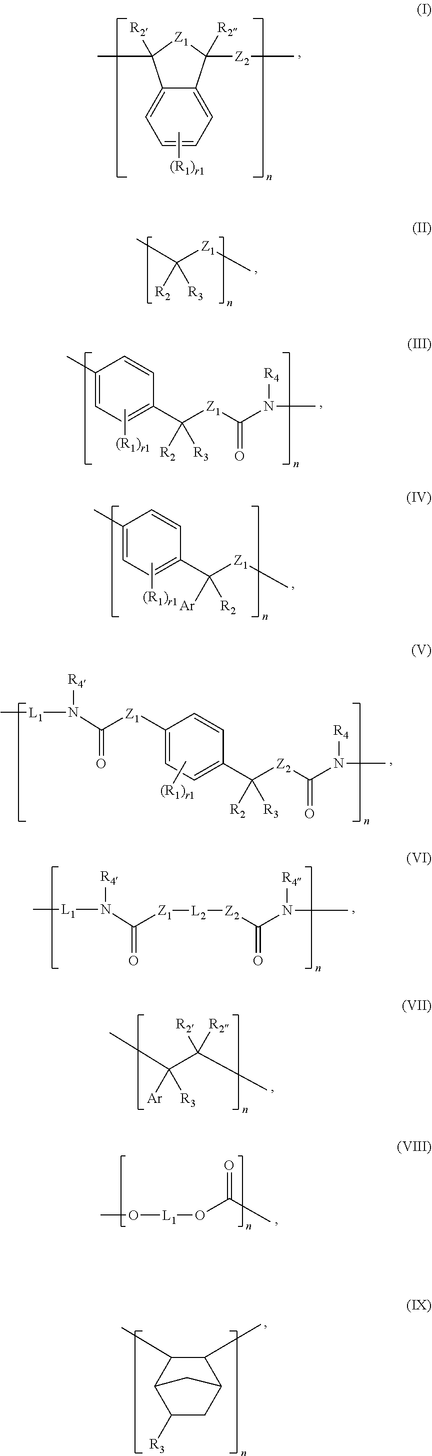 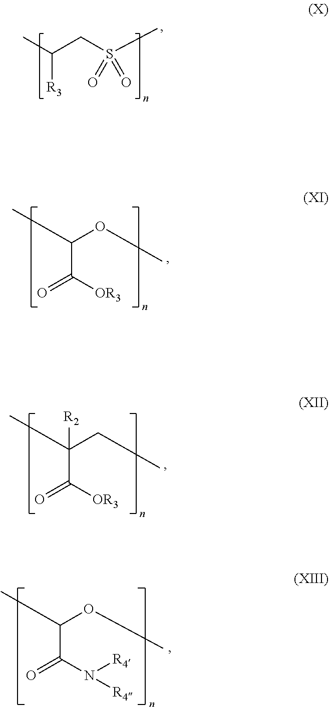
or a salt thereof, wherein:
each R₁ is, independently, H, optionally substituted alkyl, optionally substituted alkoxy, optionally substituted alkenyl, optionally substituted aryl, or halo;
each of R₂, R_{2′}, R_{2″}, and R₃ is, independently, H, optionally substituted alkyl, optionally substituted heteroalkyl, or optionally substituted aryl;
each of R₄, R_{4′}, and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein;
Ar is optionally substituted aryl, optionally substituted alkyl, or optionally substituted aralkyl;
each of L₁ and L₂ is, independently, a covalent bond, optionally substituted alkylene, optionally substituted heteroalkylene, optionally substituted arylene, or optionally substituted cycloalkylene;
each of Z₁ and Z₂ is, independently, —O—, —S—, —CR₂R₃O—, —OCR₂R₃O—, —OCR₂R₃—, —CR₂R₃S—, —SCR₂R₃S—, or —SCR₂R₃—;
r1 is an integer from 1 to 4; and
n is from about 3 to about 100,000;
wherein the SRP comprises a linear polymer or a cyclic polymer; and
wherein at least one of R₁, R₂, R_{2′}, R_{2″}, R₃, R₄, R_{4′}, R_{4″}, Ar, L₁, L₂, Z₁, or Z₂ can further optionally comprise a metal-binding moiety.

25. The method of claim 1, wherein the SRP comprises a structure of formula (Ia): 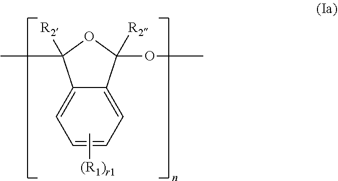
or a salt thereof, wherein:
each R₁ is, independently, H, optionally substituted alkyl, optionally substituted alkoxy, optionally substituted alkenyl, optionally substituted aryl, or halo;
each of R_{2′} and R_{2″} is, independently, H, optionally substituted alkyl, or optionally substituted aryl;
r1 is an integer from 1 to 4; and
n is from 4 to 100,000; and
wherein the SRP comprises a linear polymer or a cyclic polymer.

26. The method of claim 1, wherein the SRP comprises a structure of formula (Ib): 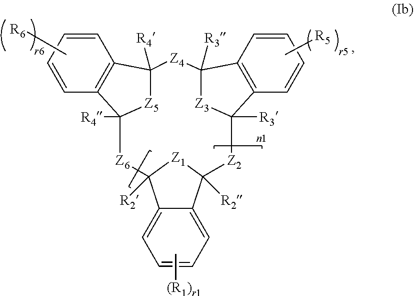
or a salt thereof, wherein:
each of R₁, R₅, and R₆ is, independently, H, optionally substituted alkyl, optionally substituted alkoxy, optionally substituted alkenyl, optionally substituted aryl, or halo;
each of R_{2′}, R_{2″}, R_{3′}, R_{3″}, R_{4′}, and R_{4″} is, independently, H, optionally substituted alkyl, or optionally substituted aryl;
each of Z₁, Z₂, Z₃, Z₄, Z₅, and Z₆ is, independently, —O—, —S—, —CR₂R₃O—,
—OCR₂R₃O—, —OCR₂R₃—, —CR₂R₃S—, —SCR₂R₃S—, or —SCR₂R₃—, in which each of R₂ and R₃ is, independently, H, optionally substituted alkyl, or optionally substituted aryl;
each of r1, r5, and r6 is, independently, an integer from 1 to 4; and
n1 is from 1 to 100.
